(19) United States
(12) Patent Application Publication
(10) Pub. No.: US 2024/0274587 A1
(43) Pub. Date: Aug. 15, 2024

(54) 3D CHIPLET INTEGRATION USING FAN-OUT WAFER-LEVEL PACKAGING

(71) Applicant: Meta Platforms Technologies, LLC, Menlo Park, CA (US)

(72) Inventors: Rajendra D. Pendse, Fremont, CA (US); Ronald Ho, Los Altos Hills, CA (US); Maryam Rahimi, Sunnyvale, CA (US); Janani Chandrasekhar, Fremont, CA (US); Jaesik Lee, San Jose, CA (US); Aswani Kurra, Surrey (CA)

(21) Appl. No.: 18/401,185

(22) Filed: Dec. 29, 2023

Related U.S. Application Data
(60) Provisional application No. 63/484,627, filed on Feb. 13, 2023.

(51) Int. Cl. H01L 25/10; H01L 23/00; H01L 23/538; H01L 25/00; H01L 25/16; H10B 80/00

(52) U.S. Cl. CPC H01L 25/105; H01L 23/5383; H01L 24/16; H01L 25/16; H01L 25/50; H10B 80/00; H01L 2224/16225

(57) ABSTRACT

A circuit assembly may include a first sub-package a first chiplet including an active frontside that includes active circuitry and faces in a first direction, a second sub-package including a second chiplet including an active frontside that includes active circuitry and faces in a second direction opposite the first direction, and a memory sub-package including a memory. The first sub-package, the second sub-package, and the memory sub-package may be arranged so as to overlap each other in the first direction. Various other devices, systems, and methods are also disclosed.

### CROSS-REFERENCE TO RELATED APPLICATIONS

This application claims the benefit of and priority to U.S. Provisional Patent Application No. 63/484,627, filed 13 Feb. 2023, and titled 3D CHIPLET INTEGRATION USING FAN-OUT WAFER-LEVEL PACKAGING, the disclosure of which is incorporated, in its entirety, by this reference.

### BRIEF DESCRIPTION OF THE DRAWINGS

The accompanying drawings illustrate a number of exemplary embodiments and are a part of the specification. Together with the following description, these drawings demonstrate and explain various principles of the present disclosure.

FIG. 1 is an illustration of an example face-to-back configuration for three-dimensional system-on-chip chiplet integration.

FIG. 2 is an illustration of an example face-to-back configuration for three-dimensional system-on-chip chiplet integration.

FIG. 3 is an illustration of an example face-to-back configuration for three-dimensional system-on-chip chiplet integration.

FIG. 4 is an illustration of an example face-to-back configuration for three-dimensional system-on-chip chiplet integration.

FIG. 5 is an illustration of an example back-to-back configuration for three-dimensional system-on-chip chiplet integration using fan-out wafer-level packaging.

FIG. 6 is an illustration of an example back-to-back configuration for three-dimensional system-on-chip chiplet integration using fan-out wafer-level packaging.

FIG. 7 is an illustration of an example back-to-back configuration for three-dimensional system-on-chip chiplet integration using fan-out wafer-level packaging.

FIG. 8 is an illustration of an example face-to-face configuration for three-dimensional system-on-chip chiplet integration using fan-out wafer-level packaging.

FIG. 9 is an illustration of an example face-to-face configuration for three-dimensional system-on-chip chiplet integration using fan-out wafer-level packaging.

FIG. 10 is an illustration of an example face-to-face configuration for three-dimensional system-on-chip chiplet integration using fan-out wafer-level packaging.

FIG. 11 is a flow diagram of an exemplary method for manufacturing a chiplet circuit assembly according to some embodiments.

FIG. 12 is an illustration of exemplary augmented-reality glasses that may be used in connection with embodiments of this disclosure.

FIG. 13 is an illustration of an exemplary virtual-reality headset that may be used in connection with embodiments of this disclosure.

FIG. 14 is an illustration of exemplary haptic devices that may be used in connection with embodiments of this disclosure.

FIG. 15 is an illustration of an exemplary virtual-reality environment according to embodiments of this disclosure.

FIG. 16 is an illustration of an exemplary augmented-reality environment according to embodiments of this disclosure.

FIG. 17 is an illustration of an exemplary system that incorporates an eye-tracking subsystem capable of tracking a user's eye(s).

FIG. 18 is a more detailed illustration of various aspects of the eye-tracking subsystem illustrated in FIG. 17.

FIGS. 19A and 19B are illustrations of an exemplary human-machine interface configured to be worn around a user's lower arm or wrist.

FIGS. 20A and 20B are illustrations of an exemplary schematic diagram with internal components of a wearable system.

Throughout the drawings, identical reference characters and descriptions indicate similar, but not necessarily identical, elements. While the exemplary embodiments described herein are susceptible to various modifications and alternative forms, specific embodiments have been shown by way of example in the drawings and will be described in detail herein. However, the exemplary embodiments described herein are not intended to be limited to the particular forms disclosed. Rather, the present disclosure covers all modifications, equivalents, and alternatives falling within the scope of the appended claims.

### DETAILED DESCRIPTION OF EXEMPLARY EMBODIMENTS

Functions of integrated circuits (ICs) are increasingly distributed into a multiple subunits, such as chiplets, that are interconnected in devices. These IC subunits may each handle a well-defined subset of functionality and can be implemented in various technologies by mixing and matching to meet the needs of specific applications. Because chiplets are often designed to handle a defined set of functions, it is possible to use a particular chiplet in multiple types of devices and systems in conjunction with other chiplets. Accordingly, the requirements for a variety of different devices may be met by selecting combinations of chiplets that are designed to support the specific needs of the devices without requiring development and manufacturing of entirely new device-specific ICs, thus reducing production costs and complexity while maintaining high degrees of optimization and performance.

Chiplets are commonly combined with each other in a single chip package via an electrical interface, such as an interposer, to route connections between the chiplets. To reduce package size and minimize routing complexity, chiplets are often arranged in a stacked configuration with a face-to-back orientation, frequently resulting in performance limitations due to excessively long electrical paths between integrated passive devices (IPDs) and active frontside regions of the chiplets. Through-silicon vias (TSVs) may be utilized to reduce path lengths of chiplet interconnections by forming shorter wiring routes passing directly through the chiplets. However, forming such TSVs through the chiplets typically involves a high degree of complexity that necessitates specialized wafer fabrications processes to form the TSVs, thus preventing the use of ready-made chiplets and substantially adding to design and fabrication costs. In some devices, IPDs may alternatively be placed in close proximity to active frontsides of chiplets, which may undesirably result in the stacked chiplet packages having excessive heights that are not optimal for many applications.

The present disclosure is generally directed to various chip package configurations that use fan-out wafer-level packaging and/or three-dimensional (3D) packaging techniques to combine multiple semiconductor chips (e.g., chiplets) and/or embedded memory (e.g., Multi Chip Package (eMCP) memory) in a fixed configuration. In some examples, 3D chiplets may be integrated using fan-out wafer level packaging in front-to-back, back-to-back, and face-to-face configurations. In some examples, a package-on-package-on-package configuration may include a 3-high subunit stack in which the functionality of a system-on-chip component is split into two sub-components (e.g., chiplets). The disclosed embodiments may enable more direct connections between active regions of two or more chiplets and/or between chiplets and one or more connected components. The embodiments may also enable reduced assembly package sizes while reducing costs and manufacturing complexity, enabling ready integration of chiplets and/or other circuit sub-units that are optimized for specific device and system requirements.

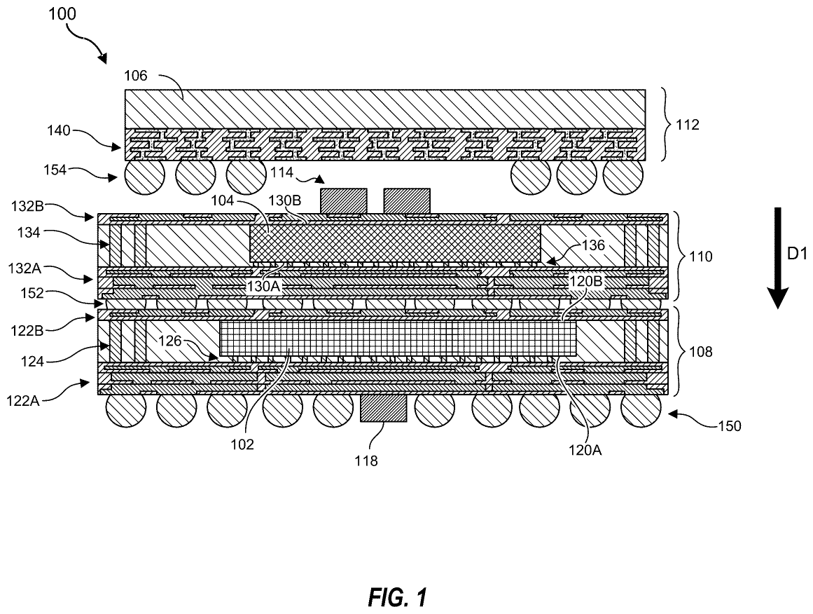

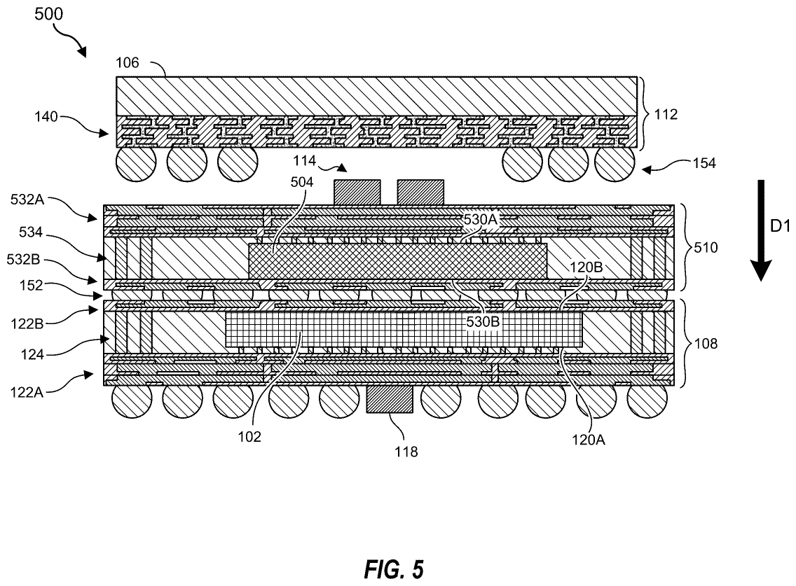

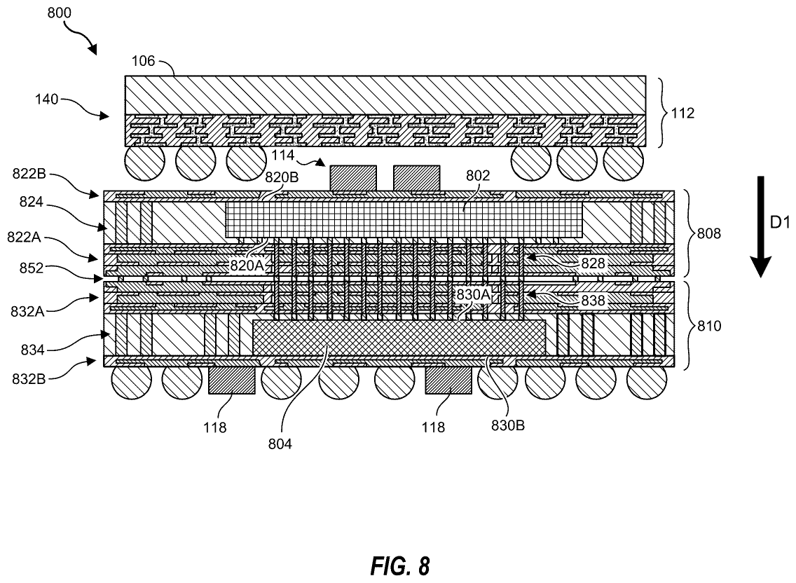

The following will provide, with reference to FIGS. 1-10, a detailed description of systems, methods, and configurations for coupling memory elements and system-on-chip (SOC) elements, such as chiplets, in stacked 3D package assemblies, in accordance with some embodiments. The discussion associated with FIGS. 1-4 relates to arrangements of SOC chiplets in face-to-back configurations. The discussion associated with FIGS. 5-7 relates to arrangements of SOC chiplets in back-to-back configurations. Additionally, the discussion associated with FIGS. 8-10 relates to arrangements of SOC chiplets in face-to-face configurations.

FIG. 1 illustrates an example packaging configuration 100 for 3D system-on-chip chiplet integration. As shown, packaging configuration 100 includes a first system-on-chip (SOC) element 102, a second SOC element 104, and a memory element 106. In some examples, first SOC element 102 and second SOC element 104 may represent or include a chiplet.

A “chiplet,” as used herein, may generally refer to a small-scale integrated circuit (IC) having a defined subset of functionality. Multiple chiplets may be combined in a single package assembly or module, with the combination of chiplets being selected and arranged to perform desired functionalities for a particular device and/or system.

In at least one example, first SOC element 102 may have one or more dimensions of less than approximately 10 mm (e.g., approximately 3 mm, approximately 4 mm, approximately 5 mm, approximately 6 mm, approximately 7 mm, approximately 8 mm, approximately 9 mm, approximately 10 mm). For example, first SOC element 102 may have one or more dimensions of about 7 mm and second SOC element 104 may have one or more dimensions of about 6 mm.

In some examples, first SOC element 102 may be included in and/or form a part of a first sub-package 108, second SOC element 104 may be included in and/or form a part of a second sub-package 110, and memory element 106 may be included in and/or form a part of a memory sub-package 112. In some examples, sub-packages 108, 110, and/or 112 may each be formed using a suitable fan-out wafer-level packaging technique or process. Sub-packages 108, 110, and/or 112 may be combined using any suitable package-on-package technology and/or process. In some examples, first and second sub-packages 108 and 110 may represent sub-packages that are joined to form a package onto which sub-package 112 may be later mounted.

As shown in FIG. 1, first and second SOC elements 102 and 104 may each have a frontside (face side, front surface, or active frontside surface) and a backside (back surface, backside surface, or substrate surface). For example, first SOC element 102 may have a frontside 120A and a backside 120B disposed opposite frontside 120A, with frontside 120A and backside 120B facing in opposite directions. Similarly, second SOC element 104 may have a frontside 130A and a backside 130B disposed on opposite sides and facing in opposite directions.

A “backside,” as used herein, may generally refer to a surface portion of semiconductor chip, such as a chiplet, that is defined by a substrate. A plurality of electronic components and/or electrically conductive layers may be formed on a surface portion of the substrate opposite the backside. In some examples, “backside” may represent or include the surface of the semiconductor chip opposite to the frontside, devoid or substantially devoid of active electronic components. According to some examples, “backside” may represent or include the part of a flip chip that faces upwards, allowing for improved heat dissipation in the configuration.

A “frontside,” as used herein, may generally refer to a portion of a semiconductor chip, such as a chiplet, that is disposed opposite the backside. The frontside may face in a direction opposite a backside of the semiconductor chip and may be defined by and/or formed adjacent electronic components and/or electrically conductive layers disposed on a substrate of the semiconductor chip. In some examples, “frontside” may represent or include the surface of the semiconductor chip where integrated circuits and other functional elements are located. For example, active circuitry, such as active electrical connection regions (e.g., electrically conductive pads such as input/output (I/O) pads), may be exposed at the frontside of the semiconductor chip. Such active electrical connection regions may be positioned and configured to be electrically coupled to one or more components external to the semiconductor chip via suitable electrical interconnects (e.g., solder and/or other electrically conductive bumps, micro-bumps, etc.). According to some examples, “frontside” may represent or include the part of a flip chip that is flipped to face downwards towards the substrate for direct electrical connections.

In the example shown in FIG. 1, first SOC element 102 and second SOC element 104 are positioned in a face-to-back arrangement, with frontside 120A of first SOC element 102 and frontside 130A of second SOC element 104 oriented facing in the same direction D1 in configuration 100. In this example, the active frontsides (i.e., face side or front surface) of both first SOC element 102 and second SOC element 104 may face in the same direction D1 (e.g., downward) and may be attached to the bottom redistribution layer of their respective sub-packages.

First SOC element 102 and second SOC element 104 may be connected to each other and memory sub-package 112 via fan-out wafer level packaging and/or other suitable 3D packaging techniques. In some examples, various redistribution layers (RDLs) may be included in first sub-package 108, second sub-package 110, and/or memory sub-package 112 to facilitate routing and interconnection between the components and sub-packages in package configuration 100. As described in further detail below, various IPDs may also be electrically coupled with first SOC element 102, second SOC element 104, and/or memory sub-package 112 via such RDLs.

An “RDL,” as used herein, may generally refer to one or more conductive layers that include wiring (e.g., via patterned wiring layers) to enable bond out and interconnection between electrically active I/O regions of components, such as active connection regions of first SOC element 102, second SOC element 104, and/or memory element 106. RDLs may also spread contact points from the active I/O regions to portions of the respective sub-packages to provide suitable bonding points that facilitate interconnection between the sub-packages and/or other external device components.

As shown in FIG. 1, first sub-package 108 and second sub-package 110 may each have top and bottom RDLs electrically coupled to each other by through-package vias (TPVs), which may include, for example, electrically conductive pillars (e.g., tall copper pillars), conductive wires (e.g., vertical wires), and/or through-mold vias. For example, first sub-package 108 may include a frontside RDL 122A adjacent frontside 120A of first SOC element 102 and a backside RDL 122B adjacent backside 120B of first SOC element 102. Active portions of first SOC element 102 at frontside 120A may be electrically coupled with frontside RDL 122A via any suitable interconnects 126 (e.g., solder bumps, copper pillar bumps, microbumps, etc.). Frontside RDL 122A and backside RDL 122B may be electrically coupled by a plurality of TPVs 124 extending through portions of first sub-package 108 located outside a periphery of first SOC element 102. Additionally, second sub-package 110 may include a frontside RDL 132A adjacent frontside 130A of second SOC element 104 and a backside RDL 132B adjacent backside 130B of second sub-package 110. Frontside RDL 132A and backside RDL 132B may be electrically coupled by a plurality of TPVs 134 extending through portions of second sub-package 110 located outside a periphery of second SOC element 104. Active portions of second SOC element 104 at frontside 130A may be electrically coupled with frontside RDL 132A via any suitable interconnects 136 (e.g., solder bumps, copper pillar bumps, microbumps, etc.).

In various embodiments, outer surfaces of RDLs in first sub-package 108, second sub-package 110, and/or memory sub-package 112 may include electrical connection regions (e.g., electrically conductive pads such as input/output (I/O) pads) configured to be connected with other sub-packages and/or device components. For example, the RDLs may include an array of electrically conductive pads that are arranged, sized, and configured to be electrically coupled to other sub-packages and/or components via suitable interconnects, such as solder balls, solder bumps, and/or microbumps. As shown in FIG. 1, an array of interconnects 150 may be disposed on a bottom surface of frontside RDL 122A of first sub-package 108. Interconnects 150 may enable mounting and electrical connection between components of packaging configuration 100 and one or more other electrical components of a device external to first sub-package 108, second sub-package 110, and memory sub-package 112. Packaging configuration 100 may also include an array of interconnects 152 disposed between a top surface of backside RDL 122B of first sub-package 108 and a bottom surface of frontside RDL 132A of second sub-package 110. Interconnects 152 may physically mount second sub-package 110 to first sub-package 108 and may provide electrical communication between first and second sub-packages 108 and 110.

In some embodiments, memory sub-package 112 of packaging configuration 100 may additionally include an RDL 140 disposed adjacent to and electrically coupled with memory element 106. Packaging configuration 100 may include an array of interconnects 154 disposed between a top surface of backside RDL 132B of second sub-package 110 and a bottom surface of RDL 140 of memory sub-package 112. Interconnects 154 may physically mount memory sub-package 112 to second sub-package 110 and may provide electrical communication between memory sub-package 112 and second sub-package 110 as well as first sub-package 108.

As illustrated, packaging configuration 100 may also include one or more passive components such as IPDs 114 and 118. IPDs may include, for example, resistors, capacitor, inductors, impedance match elements, baluns, microstriplines, and/or any other suitable electronic components either alone or in combination with a particular IPD package. In this example, IPD 118 may be electrically coupled to frontside RDL 122A of first sub-package 108, and IPDs 114 may be electrically coupled to backside RDL 132B of second sub-package 110. In another example, IPDs 118 and 114 may be electrically coupled to frontside RDL 132A of second sub-package 110 and/or backside RDL 122B of first sub-package 108. IPDs 114 shown in FIG. 1 may be disposed in a gap region between second sub-package 110 and memory sub-package 112.

As shown in FIG. 1, interconnects 154 may be sized and distributed so as to provide a space between memory sub-package 112 and second sub-package 110 suitable to accommodate IPDs 114. For example, interconnects 154 may have a suitable height to enable placement of IPDs 114 between memory sub-package 112 and second sub-package 110. Additionally, in some examples, interconnects 154 may peripherally surround a gap region between memory sub-package 112 and second sub-package 110 in which IPDs 114 are disposed. Further, interconnects 150 may be sized and distributed so as to provide a space between first sub-package 108 and an external component on which first sub-package 108 is mounted. For example, interconnects 150 may have a suitable height to enable placement of IPDs 118 on a bottom of first sub-package 108 and interconnects 150 may peripherally surround a region that includes IPDs 118.

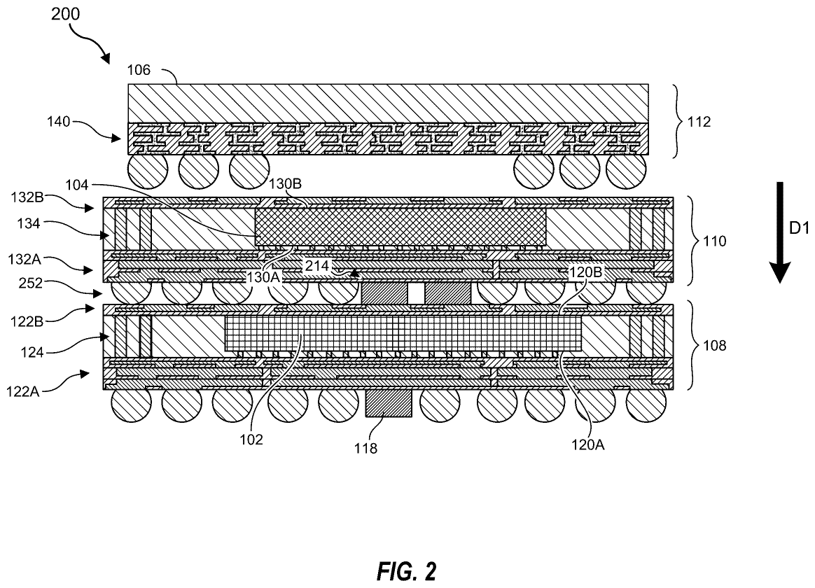

FIG. 2 is a diagram of another example face-to-back packaging configuration 200 in which at least some IPDs are disposed in a gap region between chiplet sub-packages. As shown in this example, IPDs 214 are disposed between first sub-package 108 including first SOC element 102 and second sub-package 110 including second SOC element 104. Interconnects 252 may have suitable heights between first and second sub-packages 108 and 110 so as to accommodate IPDs 214. In some examples, interconnects 252 may be arrayed so as to peripherally surround a gap region between first sub-package 108 and second sub-package 110 in which IPDs 214 are disposed.

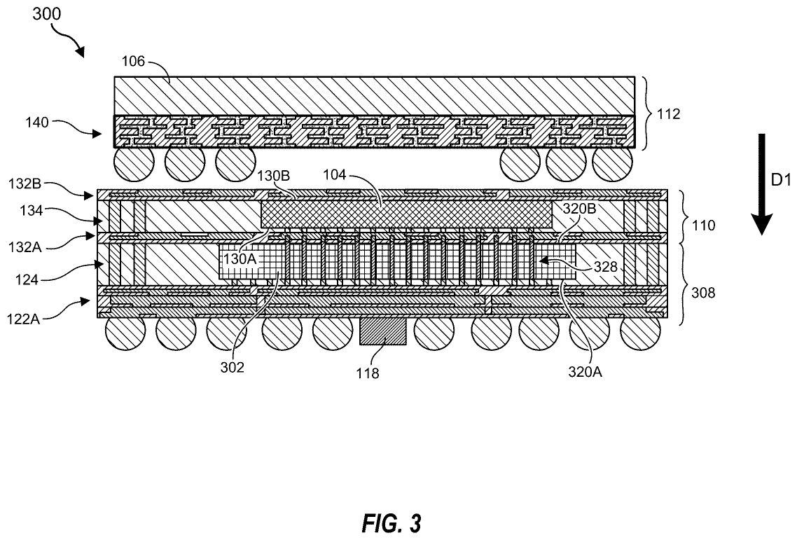

FIG. 3 illustrates an example face-to-back packaging configuration 300 for 3D SOC chiplet integration. As shown, packaging configuration 300 includes a first sub-package 308 including a first SOC element 302, a second sub-package 110 including a second SOC element 104, and a memory sub-package 112 including a memory element 106. In some examples, first and second sub-packages 308 and 110 may represent sub-packages that are joined to form a package onto which memory sub-package 112 may be later mounted. As shown in this example, second sub-package 110 may include a frontside RDL 132A and a backside RDL 132B electrically coupled by TPVs 134. Additionally, first sub-package 308 may include a frontside RDL 122A electrically coupled to frontside RDL 132A of second sub-package 110 by TPVs 124. In some examples, first sub-package 308 may additionally include a backside RDL in addition to or in place of frontside RDL 132A of second sub-package 110.

In this example, the frontsides of both of first and second SOC elements 302 and 104 are oriented facing downward in direction D1. As shown in FIG. 3, first SOC element 302 may include one or more through-silicon vias (TSVs) 328 extending through first SOC element 302 between a frontside 320A and a backside 320B of first SOC element 302. In some examples, TSVs 328 may electrically couple frontside RDL 122A of first sub-package 308 to frontside RDL 132A of second sub-package 110 and/or a frontside 130A of second SOC element 104. TSVs 328 may provide relatively shorter and more direct electrical connections between frontside 320A of first SOC element 302 and frontside 130A of second SOC element 104 and/or frontside RDL 132A of second sub-package 110. In some embodiments, one or more IPDs 118 may be mounted on first sub-package 308 adjacent frontside RDL 122A of first sub-package 308. In this example, TSVs 328 may more directly couple IPDs 118 electrically to frontside 130A of second SOC element 104 such that IPDs may effectively interface with second SOC element 104 without being mounted on second sub-package 110 (e.g., in a gap region between second sub-package 110 and memory sub-package 112).

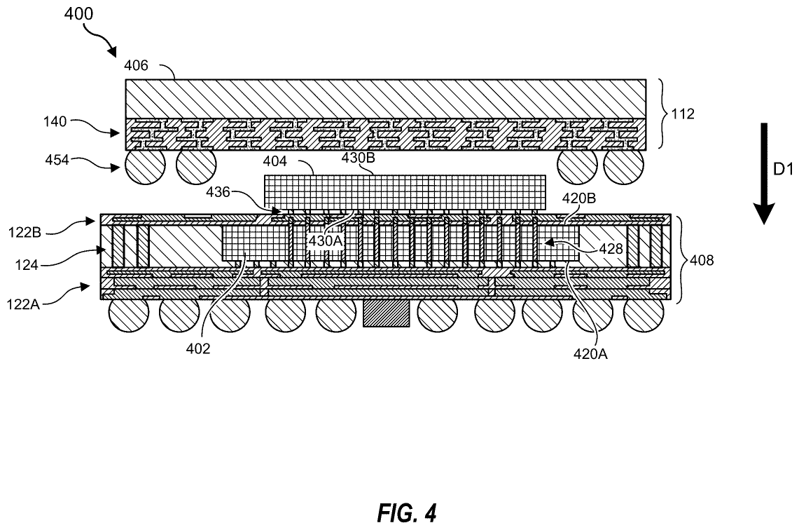

FIG. 4 illustrates an example face-to-back packaging configuration 400 for 3D SOC chiplet integration. As shown, packaging configuration 400 includes a first sub-package 408 including a first SOC element 402, a memory sub-package 112 including a memory element 106, and a second SOC element 404. First sub-package 408 may include a frontside RDL 122A and a backside RDL 122B that are electrically coupled by TPVs 124. In the example shown in FIG. 4, the frontsides 420A and 430A of both of first and second SOC elements 402 and 404, respectively, are oriented facing downward in direction D1 and frontside 430A of second SOC element 404 is mounted on a top portion of first sub-package 408, such as backside RDL 122B, via interconnects 436. In at least one example, second SOC element 404 may be mounted to first sub-package 408 using a suitable flip chip technique or process.

As shown in FIG. 4, first SOC element 402 may include one or more TSVs 428 extending through first SOC element 402 between a frontside 420A and a backside 420B of first SOC element 402. In some examples, TSVs 428 may electrically couple frontside RDL 122A to backside RDL 122B of first sub-package 408 and/or a frontside 430A of second SOC element 404. TSVs 428 may provide relatively shorter and more direct electrical connections between frontside 420A of first SOC element 402 and frontside 430A of second SOC element 404 and/or backside RDL 122B of first sub-package 408. In some embodiments, IPDs 118 may be mounted on first sub-package 408 adjacent frontside RDL 122A of first sub-package 408. In this example, TSVs 428 may more directly couple IPDs 118 electrically to frontside 430A of second SOC element 404 such that IPDs 118 may more effectively interface with second SOC element 404 without being mounted adjacent second SOC element 404 (e.g., in a gap region between second SOC element 404/first sub-package 408 and memory sub-package 112).

FIG. 5 illustrates an example back-to-back packaging configuration 500 for 3D SOC chiplet integration. As shown, packaging configuration 500 includes a first sub-package 108 including a first SOC element 102, a second sub-package 510 including a second SOC element 504, and a memory sub-package 112 including a memory element 106. In some examples, first and second sub-packages 108 and 510 may represent sub-packages that are joined to form a package onto which memory sub-package 112 may be later mounted. As shown in this example, first sub-package 108 may include a frontside RDL 122A and a backside RDL 122B electrically coupled by TPVs 124. Additionally, second sub-package 510 may include a frontside RDL 532A and a backside RDL 532B electrically coupled by TPVs 534.

In this example, a frontside 120A of first SOC element 102 and a frontside 530A of second SOC element 504 are oriented facing in opposite directions such that a backside 120B of first SOC element 102 and a backside 530B of second SOC element 504 face toward each other. As shown in FIG. 5, frontside 120A of first SOC element 102 faces downward in direction D1 and frontside 530A of second SOC element 504 faces in a direction opposite direction D1. Backside RDL 122B of first sub-package 108 may be electrically coupled to backside RDL 532B of second sub-package 510 via an array of interconnects 152.

As illustrated, packaging configuration 500 may include one or more passive components such as IPDs 114 and 118. In this example, IPD 118 may be electrically coupled to frontside RDL 122A of package 508 and IPDs 114 may be electrically coupled to frontside RDL 532A of second sub-package 510. Accordingly, IPDs 114 and 118 may each have relatively direct electrical connections to adjacent frontsides 120A and 530A of first and second SOC elements 102 and 504, respectively, thereby reducing or eliminating a need for longer wiring routes between IPDs 114 and/or 118 and first and/or second SOC elements 102 and 504 via longer electrical pathways. Moreover, such short electrical paths may also be accomplished without the use of TSVs extending through first SOC element 102 and/or second SOC element 504.

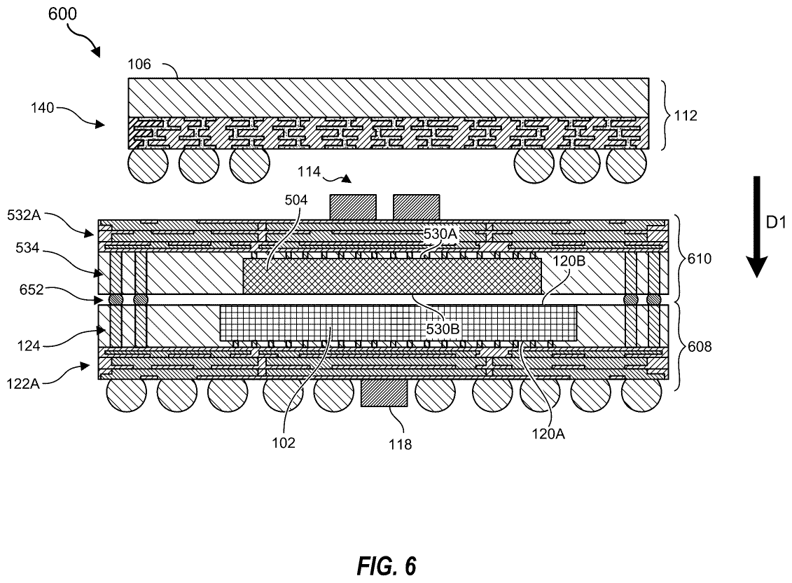

FIG. 6 illustrates an example back-to-back packaging configuration 600 for 3D SOC chiplet integration. As shown, packaging configuration 600 includes a first sub-package 608 including a first SOC element 102, a second sub-package 610 including a second SOC element 504, and a memory sub-package 112 including a memory element 106. In some examples, first and second sub-packages 608 and 610 may represent sub-packages that are joined to form a package onto which memory sub-package 112 may be later mounted. As shown in this example, first sub-package 608 may include a frontside RDL 122A and TPVs 124 extending between frontside RDL 122A and a portion of first sub-package 608 adjacent a backside 120B of first SOC element 102. Additionally, second sub-package 610 may include a frontside RDL 532A and TPVs 534 extending between frontside RDL 532A and a portion of second sub-package 610 adjacent a backside 530B of second SOC element 504.

In this example, frontside 120A of first SOC element 102 and a frontside 530A of second SOC element 504 are oriented facing in opposite directions such that a backside 120B of first SOC element 102 and a backside 530B of second SOC element 504 face toward each other. As shown in FIG. 6, frontside 120A of first SOC element 102 faces downward in direction D1 and frontside 530A of second SOC element 504 faces in a direction opposite direction D1. Frontside RDL 122A of first sub-package 608 may be electrically coupled to frontside RDL 532A of second sub-package 610 via an array of interconnects 652. For example, as illustrated in FIG. 6, interconnects 652 may be disposed between TPVs 124 and 534 so as to contact and electrically couple frontside RDL 122A of first sub-package 608 and frontside RDL 532A of second sub-package 610.

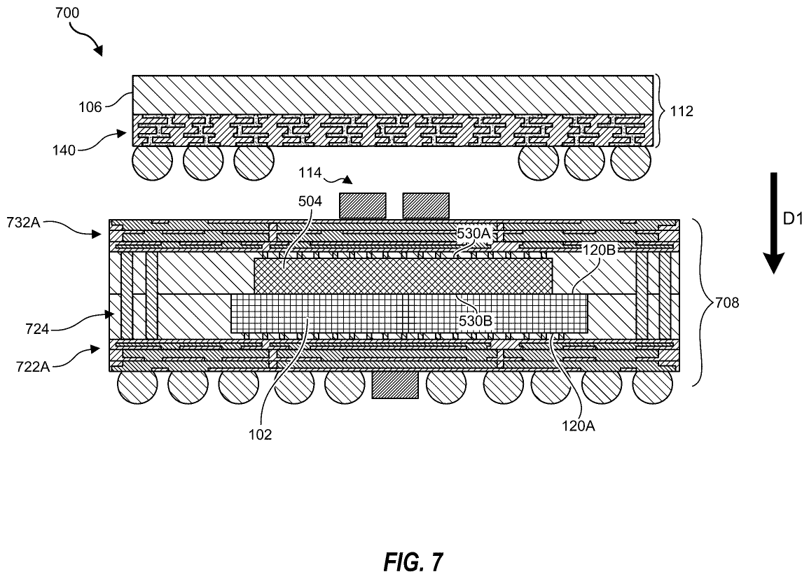

FIG. 7 illustrates an example back-to-back packaging configuration 700 for 3D SOC chiplet integration. As shown, packaging configuration 700 may include a monolithic sub-package 708 having both a first SOC element 102 and a second SOC element 504. As shown in this example, sub-package 708 may include a first frontside RDL 722A adjacent a frontside 120A of first SOC element 102. Sub-package 708 may further include a second frontside RDL 732A adjacent a frontside 530A of second SOC element 504. Sub-package 708 may also include TPVs 724 extending between and electrically coupling first frontside RDL 722A directly to second frontside RDL 732A.

In this example, frontside 120A of first SOC element 102 and frontside 530A of second SOC element 504 are oriented facing in opposite directions such that a backside 120B of first SOC element 102 and a backside 530B of second SOC element 504 face toward each other. As shown in FIG. 7, frontside 120A of first SOC element 102 faces downward in direction D1 and frontside 530A of second SOC element 504 faces in a direction opposite direction D1. Additionally, in packaging configuration 700 shown in FIG. 7, backside 120B of first SOC element 102 and backside 530B of second SOC element 504 may be disposed adjacent to and/or abutting each other within sub-package 708 so as to reduce an overall height of sub-package 708 and stacked packaging configuration 700. Back-to-back packaging configurations, such as those illustrated in FIGS. 5-7, may be manufactured without requiring chip flip processing techniques to electrically couple the SOC elements to RDLs and/or other components within the corresponding sub-packages. Accordingly, such configurations may reduce manufacturing complexity and costs that might otherwise be required in forming the assemblies through chip flip processing techniques or processes.

FIG. 8 illustrates an example face-to-face packaging configuration 800 for 3D SOC chiplet integration. As shown, packaging configuration 800 includes a first sub-package 808 including a first SOC element 802, a second sub-package 810 including a second SOC element 804, and a memory sub-package 112 including a memory element 106. In some examples, first and second sub-packages 808 and 810 may represent sub-packages that are joined to form a package onto which memory sub-package 112 may be later mounted such that first sub-package 808 is disposed between second sub-package 810 and memory sub-package 112. As shown in this example, first sub-package 808 may include a frontside RDL 822A and a backside RDL 822B electrically coupled by TPVs 824. Additionally, second sub-package 810 may include a frontside RDL 832A and a backside RDL 832B electrically coupled by TPVs 834.

In this example, a frontside 820A of first SOC element 802 and a frontside 830A of second SOC element 804 are oriented facing in opposite directions such that frontside 820A and frontside 830A face toward each other, and such that a backside 820B of first SOC element 802 and a backside 830B of second SOC element 804 face away from each other. As shown in FIG. 8, frontside 820A of first SOC element 802 faces downward in direction D1 and frontside 830A of second SOC element 804 faces in a direction opposite direction D1. Backside RDL 822B of first sub-package 808 may be electrically coupled to backside RDL 832B of second sub-package 810 via an array of interconnects 852.

As illustrated, first sub-package 808 may include through-RDL vias (TRVs) 828 extending from frontside 820A of first SOC element 802 through frontside RDL 822A of first sub-package 808. Additionally, second sub-package 810 may include TRVs 838 extending from frontside 830A of second SOC element 804 through frontside RDL 832A of second sub-package 810. TRVs 828 and 838 may be electrically connected via corresponding interconnects 852 disposed therebetween. In some examples, electrical connections between first sub-package 808 and second sub-package 810 may be formed using any suitable techniques and/or processes, such as fine pitch package-to-package stacking. Accordingly, active regions of frontsides 820A and 830A of first and second SOC elements 802 and 804 may be more directly connected to each other through TRVs 828 and 838.

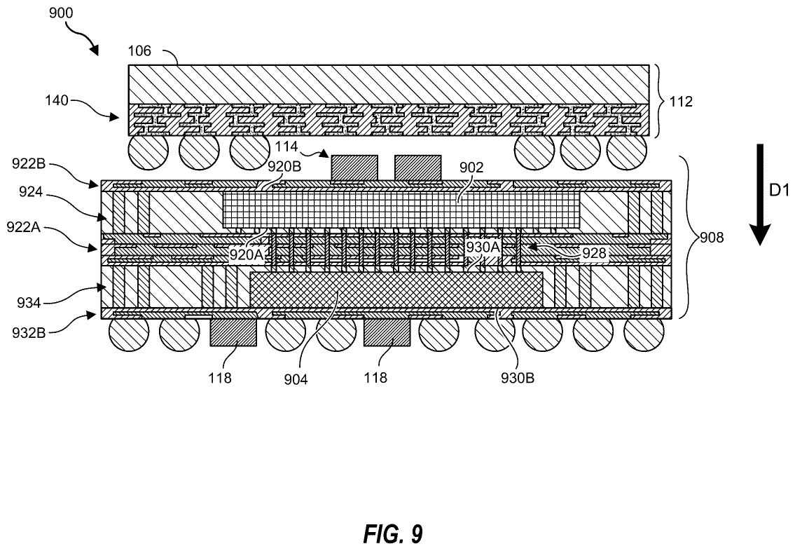

FIG. 9 illustrates an example face-to-face packaging configuration 900 for 3D SOC chiplet integration. As shown, packaging configuration 900 includes a memory sub-package 112 including a memory element 106 and a sub-package 908 that includes a first SOC element 902 and a second SOC element 904. In some examples, sub-package 908 may include a first backside RDL 922B and a frontside RDL 922A electrically coupled to each other by TPVs 924. Additionally, sub-package 908 may include a second backside RDL 932B that is electrically coupled to frontside RDL 922A by TPVs 934. Frontside RDL 922A may be disposed between first SOC element 902 and second SOC element 904 adjacent a frontside 920A of first SOC element 902 and a frontside 930A of second SOC element 904.

In this example, frontside 920A of first SOC element 902 and frontside 930A of second SOC element 904 are oriented facing in opposite directions such that frontside 920A and frontside 930A face toward each other, and such that a backside 920B of first SOC element 902 and a backside 930B of second SOC element 904 face away from each other. As shown in FIG. 9, frontside 920A of first SOC element 902 faces downward in direction D1 and frontside 930A of second SOC element 904 faces in a direction opposite direction D1. First backside RDL 922B may be electrically coupled to second backside RDL 932B via TPVs 924, TPVs 934, and frontside RDL 922A. As illustrated, sub-package 908 may include TRVs 928 extending from frontside 920A of first SOC element 902 through frontside RDL 922A toward frontside 930A of second SOC element 904. Accordingly, active regions of frontsides 920A and 930A of first and second SOC elements 902 and 904 may be more directly connected to each other through TRVs 928.

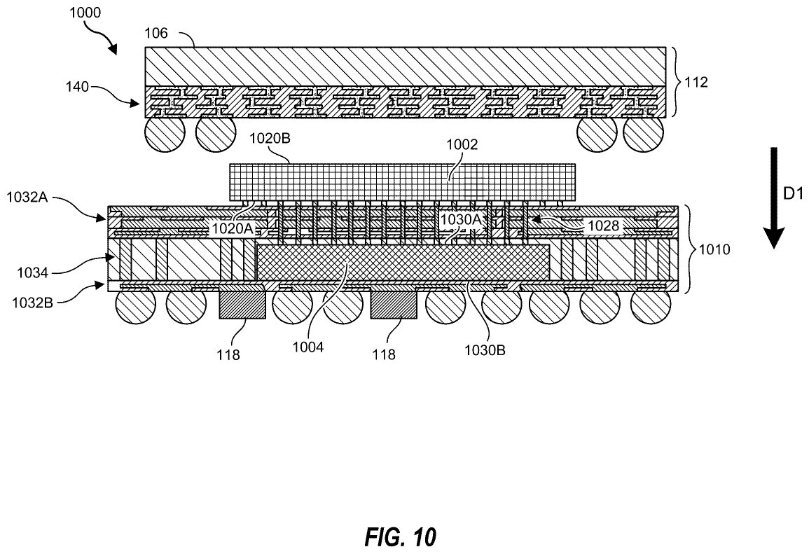

FIG. 10 illustrates an example face-to-face packaging configuration 1000 for 3D SOC chiplet integration. As shown, packaging configuration 1000 includes a memory sub-package 112 including a memory element 106, a first SOC element 1002, and a sub-package 1010 that includes a second SOC element 1004. First SOC element 1002 may be mounted to sub-package 1010. In some examples, sub-package 1010 may include a backside RDL 1032B and a frontside RDL 1032A electrically coupled to each other by TPVs 1034. Frontside RDL 1032A may be disposed between first SOC element 1002 and second SOC element 1004 adjacent a frontside 1020A of first SOC element 1002 and a frontside 1030A of second SOC element 1004.

In this example, frontside 1020A of first SOC element 1002 and frontside 1030A of second SOC element 1004 are oriented facing in opposite directions such that frontside 1020A and frontside 1030A face toward each other, and such that a backside 1020B of first SOC element 1002 and a backside 1030B of second SOC element 1004 face away from each other. As shown in FIG. 10, frontside 1020A of first SOC element 1002 faces downward in direction D1 and frontside 1030A of second SOC element 1004 faces in a direction opposite direction D1. As illustrated, sub-package 1010 may include TRVs 1028 extending from frontside 1020A of first SOC element 1002 through frontside RDL 1032A toward frontside 1030A of second SOC element 1004. Accordingly, active regions of frontsides 1020A and 1030A of first and second SOC elements 1002 and 1004 may be more directly connected to each other through TRVs 1028. Additionally, as shown in FIG. 10, IPDs 118 may be mounted on sub-package 1010 adjacent backside RDL 1032B of sub-package 1010. In this example, TRVs 1028 may more directly couple IPDs 118 electrically to frontside 1030A of second SOC element 1004 and/or frontside 1020A of first SOC element 1002 such that IPDs 118 may more effectively interface with first and second SOC elements 1002 and 1004.

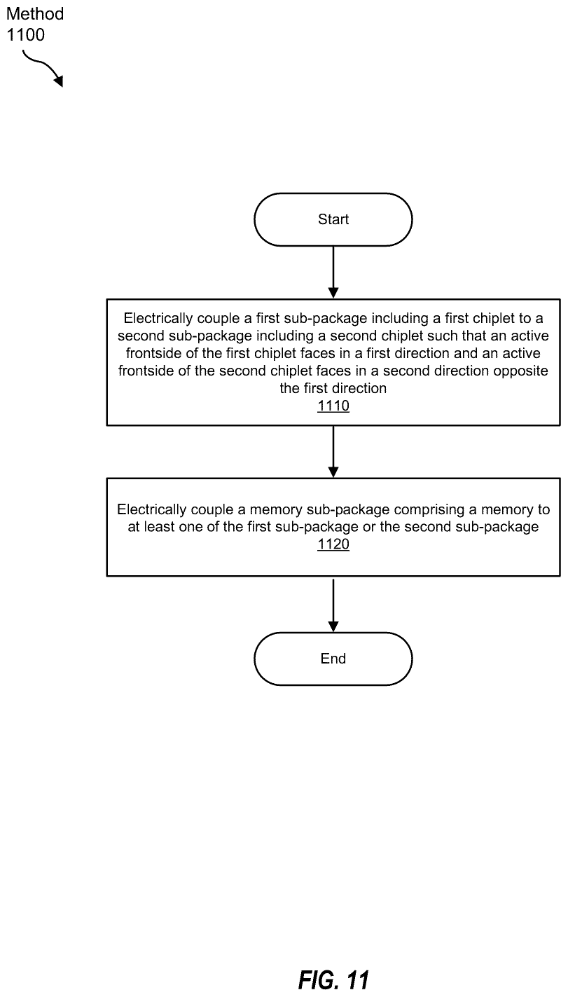

FIG. 11 is a flow diagram of an exemplary method 1100 for manufacturing a chiplet circuit assembly in accordance with embodiments of this disclosure. As illustrated in FIG. 11, at step 1110, a first sub-package including a first chiplet may be electrically coupled to a second sub-package including a second chiplet such that an active frontside of the first chiplet faces in a first direction and an active frontside of the second chiplet faces in a second direction opposite the first direction. In this embodiment, the active frontside of the first chiplet and the active frontside of the second chiplet may each include active circuitry.

At step 1120 in FIG. 11, a memory sub-package including a memory may be electrically coupled to at least one of the first sub-package or the second sub-package. In some embodiments, at least one IPD may be mounted to at least one of the first sub-package or the second sub-package such that the at least one IPD is positioned between the memory sub-package and the at least one of the first sub-package or the second sub-package.

Embodiments of the present disclosure may include or be implemented in conjunction with various types of artificial-reality systems. Artificial reality is a form of reality that has been adjusted in some manner before presentation to a user, which may include, for example, a virtual reality, an augmented reality, a mixed reality, a hybrid reality, or some combination and/or derivative thereof. Artificial-reality content may include completely computer-generated content or computer-generated content combined with captured (e.g., real-world) content. The artificial-reality content may include video, audio, haptic feedback, or some combination thereof, any of which may be presented in a single channel or in multiple channels (such as stereo video that produces a three-dimensional (3D) effect to the viewer). Additionally, in some embodiments, artificial reality may also be associated with applications, products, accessories, services, or some combination thereof, that are used to, for example, create content in an artificial reality and/or are otherwise used in (e.g., to perform activities in) an artificial reality.

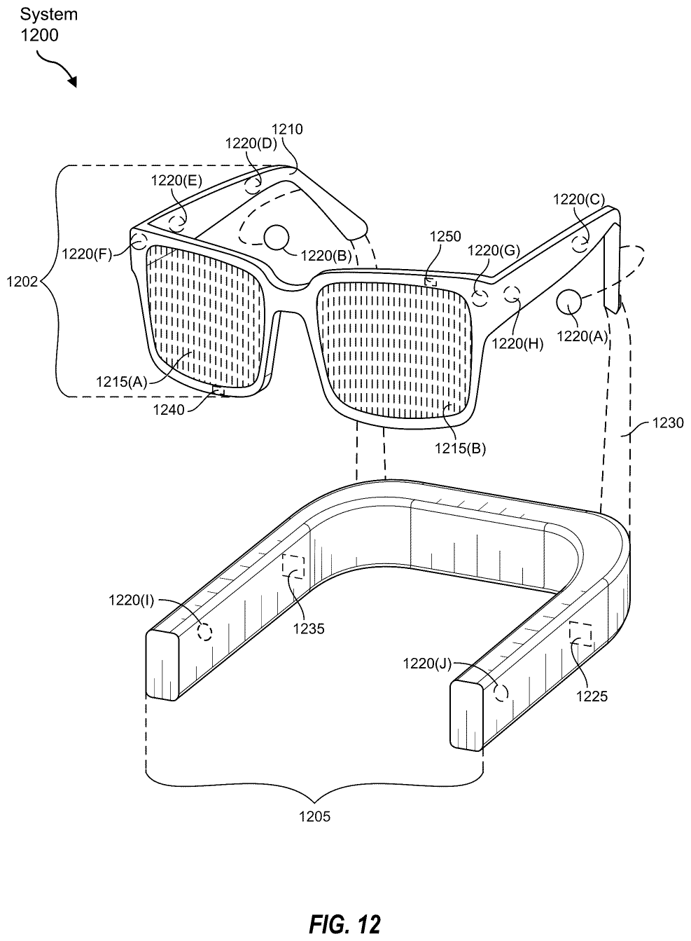

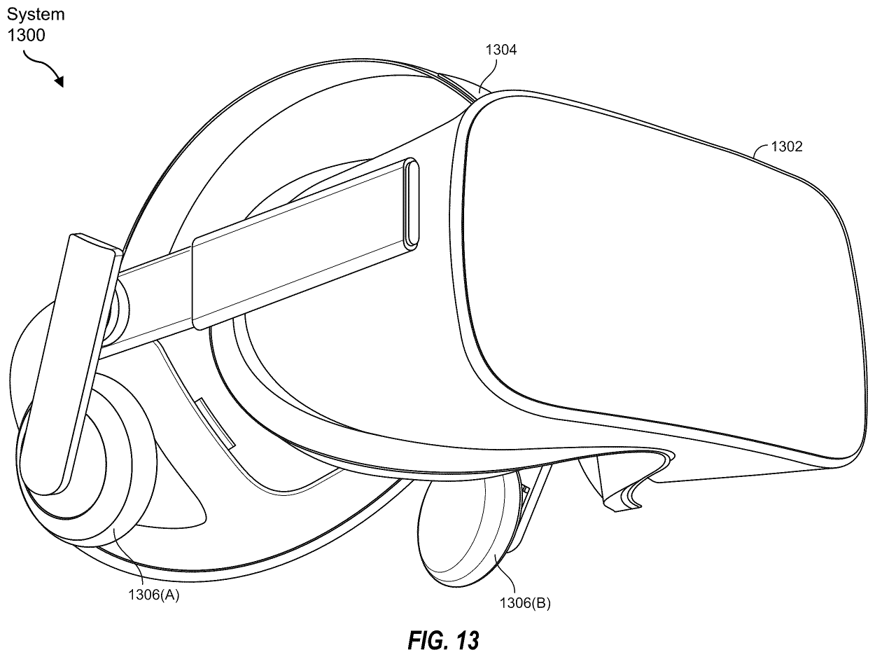

Artificial-reality systems may be implemented in a variety of different form factors and configurations. Some artificial-reality systems may be designed to work without near-eye displays (NEDs). Other artificial-reality systems may include an NED that also provides visibility into the real world (such as, e.g., augmented-reality system 1200 in FIG. 12) or that visually immerses a user in an artificial reality (such as, e.g., virtual-reality system 1300 in FIG. 13). While some artificial-reality devices may be self-contained systems, other artificial-reality devices may communicate and/or coordinate with external devices to provide an artificial-reality experience to a user. Examples of such external devices include handheld controllers, mobile devices, desktop computers, devices worn by a user, devices worn by one or more other users, and/or any other suitable external system.

Turning to FIG. 12, augmented-reality system 1200 may include an eyewear device 1202 with a frame 1210 configured to hold a left display device 1215(A) and a right display device 1215(B) in front of a user's eyes. Display devices 1215(A) and 1215(B) may act together or independently to present an image or series of images to a user. While augmented-reality system 1200 includes two displays, embodiments of this disclosure may be implemented in augmented-reality systems with a single NED or more than two NEDs.

In some embodiments, augmented-reality system 1200 may include one or more sensors, such as sensor 1240. Sensor 1240 may generate measurement signals in response to motion of augmented-reality system 1200 and may be located on substantially any portion of frame 1210. Sensor 1240 may represent one or more of a variety of different sensing mechanisms, such as a position sensor, an inertial measurement unit (IMU), a depth camera assembly, a structured light emitter and/or detector, or any combination thereof. In some embodiments, augmented-reality system 1200 may or may not include sensor 1240 or may include more than one sensor. In embodiments in which sensor 1240 includes an IMU, the IMU may generate calibration data based on measurement signals from sensor 1240. Examples of sensor 1240 may include, without limitation, accelerometers, gyroscopes, magnetometers, other suitable types of sensors that detect motion, sensors used for error correction of the IMU, or some combination thereof.

In some examples, augmented-reality system 1200 may also include a microphone array with a plurality of acoustic transducers 1220(A)-1220(J), referred to collectively as acoustic transducers 1220. Acoustic transducers 1220 may represent transducers that detect air pressure variations induced by sound waves. Each acoustic transducer 1220 may be configured to detect sound and convert the detected sound into an electronic format (e.g., an analog or digital format). The microphone array in FIG. 12 may include, for example, ten acoustic transducers: 1220(A) and 1220(B), which may be designed to be placed inside a corresponding ear of the user, acoustic transducers 1220(C), 1220(D), 1220(E), 1220(F), 1220(G), and 1220(H), which may be positioned at various locations on frame 1210, and/or acoustic transducers 1220(I) and 1220(J), which may be positioned on a corresponding neckband 1205.

In some embodiments, one or more of acoustic transducers 1220(A)-(J) may be used as output transducers (e.g., speakers). For example, acoustic transducers 1220(A) and/or 1220(B) may be earbuds or any other suitable type of headphone or speaker.

The configuration of acoustic transducers 1220 of the microphone array may vary. While augmented-reality system 1200 is shown in FIG. 12 as having ten acoustic transducers 1220, the number of acoustic transducers 1220 may be greater or less than ten. In some embodiments, using higher numbers of acoustic transducers 1220 may increase the amount of audio information collected and/or the sensitivity and accuracy of the audio information. In contrast, using a lower number of acoustic transducers 1220 may decrease the computing power required by an associated controller 1250 to process the collected audio information. In addition, the position of each acoustic transducer 1220 of the microphone array may vary. For example, the position of an acoustic transducer 1220 may include a defined position on the user, a defined coordinate on frame 1210, an orientation associated with each acoustic transducer 1220, or some combination thereof.

Acoustic transducers 1220(A) and 1220(B) may be positioned on different parts of the user's ear, such as behind the pinna, behind the tragus, and/or within the auricle or fossa. Or, there may be additional acoustic transducers 1220 on or surrounding the ear in addition to acoustic transducers 1220 inside the ear canal. Having an acoustic transducer 1220 positioned next to an ear canal of a user may enable the microphone array to collect information on how sounds arrive at the ear canal. By positioning at least two of acoustic transducers 1220 on either side of a user's head (e.g., as binaural microphones), augmented-reality device 1200 may simulate binaural hearing and capture a 3D stereo sound field around about a user's head. In some embodiments, acoustic transducers 1220(A) and 1220(B) may be connected to augmented-reality system 1200 via a wired connection 1230, and in other embodiments acoustic transducers 1220(A) and 1220(B) may be connected to augmented-reality system 1200 via a wireless connection (e.g., a BLUETOOTH connection). In still other embodiments, acoustic transducers 1220(A) and 1220(B) may not be used at all in conjunction with augmented-reality system 1200.

Acoustic transducers 1220 on frame 1210 may be positioned in a variety of different ways, including along the length of the temples, across the bridge, above or below display devices 1215(A) and 1215(B), or some combination thereof. Acoustic transducers 1220 may also be oriented such that the microphone array is able to detect sounds in a wide range of directions surrounding the user wearing the augmented-reality system 1200. In some embodiments, an optimization process may be performed during manufacturing of augmented-reality system 1200 to determine relative positioning of each acoustic transducer 1220 in the microphone array.

In some examples, augmented-reality system 1200 may include or be connected to an external device (e.g., a paired device), such as neckband 1205. Neckband 1205 generally represents any type or form of paired device. Thus, the following discussion of neckband 1205 may also apply to various other paired devices, such as charging cases, smart watches, smart phones, wrist bands, other wearable devices, hand-held controllers, tablet computers, laptop computers, other external compute devices, etc.

As shown, neckband 1205 may be coupled to eyewear device 1202 via one or more connectors. The connectors may be wired or wireless and may include electrical and/or non-electrical (e.g., structural) components. In some cases, eyewear device 1202 and neckband 1205 may operate independently without any wired or wireless connection between them. While FIG. 12 illustrates the components of eyewear device 1202 and neckband 1205 in example locations on eyewear device 1202 and neckband 1205, the components may be located elsewhere and/or distributed differently on eyewear device 1202 and/or neckband 1205. In some embodiments, the components of eyewear device 1202 and neckband 1205 may be located on one or more additional peripheral devices paired with eyewear device 1202, neckband 1205, or some combination thereof.

Pairing external devices, such as neckband 1205, with augmented-reality eyewear devices may enable the eyewear devices to achieve the form factor of a pair of glasses while still providing sufficient battery and computation power for expanded capabilities. Some or all of the battery power, computational resources, and/or additional features of augmented-reality system 1200 may be provided by a paired device or shared between a paired device and an eyewear device, thus reducing the weight, heat profile, and form factor of the eyewear device overall while still retaining desired functionality. For example, neckband 1205 may allow components that would otherwise be included on an eyewear device to be included in neckband 1205 since users may tolerate a heavier weight load on their shoulders than they would tolerate on their heads. Neckband 1205 may also have a larger surface area over which to diffuse and disperse heat to the ambient environment. Thus, neckband 1205 may allow for greater battery and computation capacity than might otherwise have been possible on a stand-alone eyewear device. Since weight carried in neckband 1205 may be less invasive to a user than weight carried in eyewear device 1202, a user may tolerate wearing a lighter eyewear device and carrying or wearing the paired device for greater lengths of time than a user would tolerate wearing a heavy standalone eyewear device, thereby enabling users to more fully incorporate artificial-reality environments into their day-to-day activities.

Neckband 1205 may be communicatively coupled with eyewear device 1202 and/or to other devices. These other devices may provide certain functions (e.g., tracking, localizing, depth mapping, processing, storage, etc.) to augmented-reality system 1200. In the embodiment of FIG. 12, neckband 1205 may include two acoustic transducers (e.g., 1220(I) and 1220(J)) that are part of the microphone array (or potentially form their own microphone subarray). Neckband 1205 may also include a controller 1225 and a power source 1235.

Acoustic transducers 1220(I) and 1220(J) of neckband 1205 may be configured to detect sound and convert the detected sound into an electronic format (analog or digital). In the embodiment of FIG. 12, acoustic transducers 1220(I) and 1220(J) may be positioned on neckband 1205, thereby increasing the distance between the neckband acoustic transducers 1220(I) and 1220(J) and other acoustic transducers 1220 positioned on eyewear device 1202. In some cases, increasing the distance between acoustic transducers 1220 of the microphone array may improve the accuracy of beamforming performed via the microphone array. For example, if a sound is detected by acoustic transducers 1220(C) and 1220(D) and the distance between acoustic transducers 1220(C) and 1220(D) is greater than, e.g., the distance between acoustic transducers 1220(D) and 1220(E), the determined source location of the detected sound may be more accurate than if the sound had been detected by acoustic transducers 1220(D) and 1220(E).

Controller 1225 of neckband 1205 may process information generated by the sensors on neckband 1205 and/or augmented-reality system 1200. For example, controller 1225 may process information from the microphone array that describes sounds detected by the microphone array. For each detected sound, controller 1225 may perform a direction-of-arrival (DOA) estimation to estimate a direction from which the detected sound arrived at the microphone array. As the microphone array detects sounds, controller 1225 may populate an audio data set with the information. In embodiments in which augmented-reality system 1200 includes an inertial measurement unit, controller 1225 may compute all inertial and spatial calculations from the IMU located on eyewear device 1202. A connector may convey information between augmented-reality system 1200 and neckband 1205 and between augmented-reality system 1200 and controller 1225. The information may be in the form of optical data, electrical data, wireless data, or any other transmittable data form. Moving the processing of information generated by augmented-reality system 1200 to neckband 1205 may reduce weight and heat in eyewear device 1202, making it more comfortable to the user.

Power source 1235 in neckband 1205 may provide power to eyewear device 1202 and/or to neckband 1205. Power source 1235 may include, without limitation, lithium ion batteries, lithium-polymer batteries, primary lithium batteries, alkaline batteries, or any other form of power storage. In some cases, power source 1235 may be a wired power source. Including power source 1235 on neckband 1205 instead of on eyewear device 1202 may help better distribute the weight and heat generated by power source 1235.

As noted, some artificial-reality systems may, instead of blending an artificial reality with actual reality, substantially replace one or more of a user's sensory perceptions of the real world with a virtual experience. One example of this type of system is a head-worn display system, such as virtual-reality system 1300 in FIG. 13, that mostly or completely covers a user's field of view. Virtual-reality system 1300 may include a front rigid body 1302 and a band 1304 shaped to fit around a user's head. Virtual-reality system 1300 may also include output audio transducers 1306(A) and 1306(B). Furthermore, while not shown in FIG. 13, front rigid body 1302 may include one or more electronic elements, including one or more electronic displays, one or more inertial measurement units (IMUs), one or more tracking emitters or detectors, and/or any other suitable device or system for creating an artificial-reality experience.

Artificial-reality systems may include a variety of types of visual feedback mechanisms. For example, display devices in augmented-reality system 1200 and/or virtual-reality system 1300 may include one or more liquid crystal displays (LCDs), light emitting diode (LED) displays, microLED displays, organic LED (OLED) displays, digital light project (DLP) micro-displays, liquid crystal on silicon (LCoS) micro-displays, and/or any other suitable type of display screen. These artificial-reality systems may include a single display screen for both eyes or may provide a display screen for each eye, which may allow for additional flexibility for varifocal adjustments or for correcting a user's refractive error. Some of these artificial-reality systems may also include optical subsystems having one or more lenses (e.g., concave or convex lenses, Fresnel lenses, adjustable liquid lenses, etc.) through which a user may view a display screen. These optical subsystems may serve a variety of purposes, including to collimate (e.g., make an object appear at a greater distance than its physical distance), to magnify (e.g., make an object appear larger than its actual size), and/or to relay (to, e.g., the viewer's eyes) light. These optical subsystems may be used in a non-pupil-forming architecture (such as a single lens configuration that directly collimates light but results in so-called pincushion distortion) and/or a pupil-forming architecture (such as a multi-lens configuration that produces so-called barrel distortion to nullify pincushion distortion).

In addition to or instead of using display screens, some of the artificial-reality systems described herein may include one or more projection systems. For example, display devices in augmented-reality system 1200 and/or virtual-reality system 1300 may include micro-LED projectors that project light (using, e.g., a waveguide) into display devices, such as clear combiner lenses that allow ambient light to pass through. The display devices may refract the projected light toward a user's pupil and may enable a user to simultaneously view both artificial-reality content and the real world. The display devices may accomplish this using any of a variety of different optical components, including waveguide components (e.g., holographic, planar, diffractive, polarized, and/or reflective waveguide elements), light-manipulation surfaces and elements (such as diffractive, reflective, and refractive elements and gratings), coupling elements, etc. Artificial-reality systems may also be configured with any other suitable type or form of image projection system, such as retinal projectors used in virtual retina displays.

The artificial-reality systems described herein may also include various types of computer vision components and subsystems. For example, augmented-reality system 1200 and/or virtual-reality system 1300 may include one or more optical sensors, such as two-dimensional (2D) or 3D cameras, structured light transmitters and detectors, time-of-flight depth sensors, single-beam or sweeping laser rangefinders, 3D LiDAR sensors, and/or any other suitable type or form of optical sensor. An artificial-reality system may process data from one or more of these sensors to identify a location of a user, to map the real world, to provide a user with context about real-world surroundings, and/or to perform a variety of other functions.

The artificial-reality systems described herein may also include one or more input and/or output audio transducers. Output audio transducers may include voice coil speakers, ribbon speakers, electrostatic speakers, piezoelectric speakers, bone conduction transducers, cartilage conduction transducers, tragus-vibration transducers, and/or any other suitable type or form of audio transducer. Similarly, input audio transducers may include condenser microphones, dynamic microphones, ribbon microphones, and/or any other type or form of input transducer. In some embodiments, a single transducer may be used for both audio input and audio output.

In some embodiments, the artificial-reality systems described herein may also include tactile (i.e., haptic) feedback systems, which may be incorporated into headwear, gloves, body suits, handheld controllers, environmental devices (e.g., chairs, floormats, etc.), and/or any other type of device or system. Haptic feedback systems may provide various types of cutaneous feedback, including vibration, force, traction, texture, and/or temperature. Haptic feedback systems may also provide various types of kinesthetic feedback, such as motion and compliance. Haptic feedback may be implemented using motors, piezoelectric actuators, fluidic systems, and/or a variety of other types of feedback mechanisms. Haptic feedback systems may be implemented independent of other artificial-reality devices, within other artificial-reality devices, and/or in conjunction with other artificial-reality devices.

By providing haptic sensations, audible content, and/or visual content, artificial-reality systems may create an entire virtual experience or enhance a user's real-world experience in a variety of contexts and environments. For instance, artificial-reality systems may assist or extend a user's perception, memory, or cognition within a particular environment. Some systems may enhance a user's interactions with other people in the real world or may enable more immersive interactions with other people in a virtual world. Artificial-reality systems may also be used for educational purposes (e.g., for teaching or training in schools, hospitals, government organizations, military organizations, business enterprises, etc.), entertainment purposes (e.g., for playing video games, listening to music, watching video content, etc.), and/or for accessibility purposes (e.g., as hearing aids, visual aids, etc.). The embodiments disclosed herein may enable or enhance a user's artificial-reality experience in one or more of these contexts and environments and/or in other contexts and environments.

As noted, artificial-reality systems 1200 and 1300 may be used with a variety of other types of devices to provide a more compelling artificial-reality experience. These devices may be haptic interfaces with transducers that provide haptic feedback and/or that collect haptic information about a user's interaction with an environment. The artificial-reality systems disclosed herein may include various types of haptic interfaces that detect or convey various types of haptic information, including tactile feedback (e.g., feedback that a user detects via nerves in the skin, which may also be referred to as cutaneous feedback) and/or kinesthetic feedback (e.g., feedback that a user detects via receptors located in muscles, joints, and/or tendons).

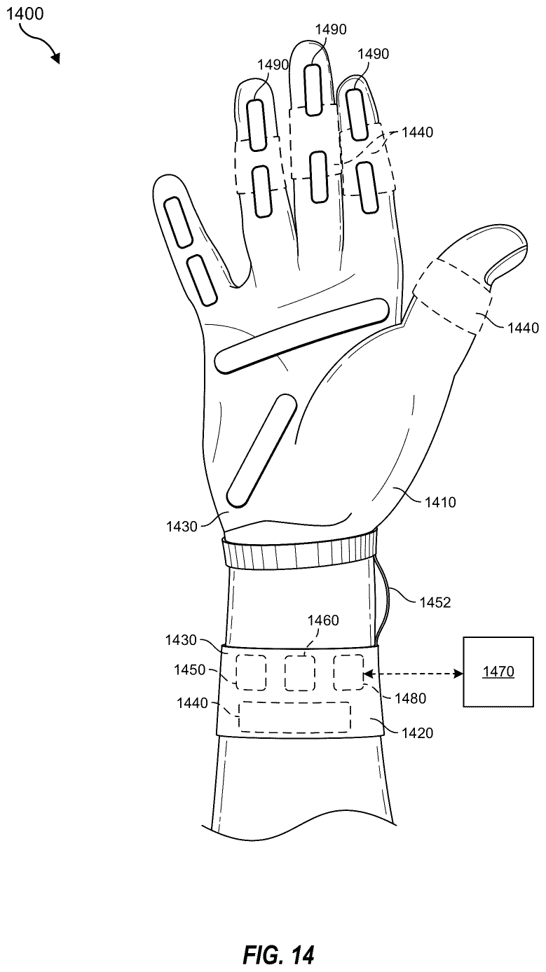

Haptic feedback may be provided by interfaces positioned within a user's environment (e.g., chairs, tables, floors, etc.) and/or interfaces on articles that may be worn or carried by a user (e.g., gloves, wristbands, etc.). As an example, FIG. 14 illustrates a vibrotactile system 1400 in the form of a wearable glove (haptic device 1410) and wristband (haptic device 1420). Haptic device 1410 and haptic device 1420 are shown as examples of wearable devices that include a flexible, wearable textile material 1430 that is shaped and configured for positioning against a user's hand and wrist, respectively. This disclosure also includes vibrotactile systems that may be shaped and configured for positioning against other human body parts, such as a finger, an arm, a head, a torso, a foot, or a leg. By way of example and not limitation, vibrotactile systems according to various embodiments of the present disclosure may also be in the form of a glove, a headband, an armband, a sleeve, a head covering, a sock, a shirt, or pants, among other possibilities. In some examples, the term “textile” may include any flexible, wearable material, including woven fabric, non-woven fabric, leather, cloth, a flexible polymer material, composite materials, etc.

One or more vibrotactile devices 1440 may be positioned at least partially within one or more corresponding pockets formed in textile material 1430 of vibrotactile system 1400. Vibrotactile devices 1440 may be positioned in locations to provide a vibrating sensation (e.g., haptic feedback) to a user of vibrotactile system 1400. For example, vibrotactile devices 1440 may be positioned against the user's finger(s), thumb, or wrist, as shown in FIG. 14. Vibrotactile devices 1440 may, in some examples, be sufficiently flexible to conform to or bend with the user's corresponding body part(s).

A power source 1450 (e.g., a battery) for applying a voltage to the vibrotactile devices 1440 for activation thereof may be electrically coupled to vibrotactile devices 1440, such as via conductive wiring 1452. In some examples, each of vibrotactile devices 1440 may be independently electrically coupled to power source 1450 for individual activation. In some embodiments, a processor 1460 may be operatively coupled to power source 1450 and configured (e.g., programmed) to control activation of vibrotactile devices 1440.

Vibrotactile system 1400 may be implemented in a variety of ways. In some examples, vibrotactile system 1400 may be a standalone system with integral subsystems and components for operation independent of other devices and systems. As another example, vibrotactile system 1400 may be configured for interaction with another device or system 1470. For example, vibrotactile system 1400 may, in some examples, include a communications interface 1480 for receiving and/or sending signals to the other device or system 1470. The other device or system 1470 may be a mobile device, a gaming console, an artificial-reality (e.g., virtual-reality, augmented-reality, mixed-reality) device, a personal computer, a tablet computer, a network device (e.g., a modem, a router, etc.), a handheld controller, etc. Communications interface 1480 may enable communications between vibrotactile system 1400 and the other device or system 1470 via a wireless (e.g., Wi-Fi, BLUETOOTH, cellular, radio, etc.) link or a wired link. If present, communications interface 1480 may be in communication with processor 1460, such as to provide a signal to processor 1460 to activate or deactivate one or more of the vibrotactile devices 1440.

Vibrotactile system 1400 may optionally include other subsystems and components, such as touch-sensitive pads 1490, pressure sensors, motion sensors, position sensors, lighting elements, and/or user interface elements (e.g., an on/off button, a vibration control element, etc.). During use, vibrotactile devices 1440 may be configured to be activated for a variety of different reasons, such as in response to the user's interaction with user interface elements, a signal from the motion or position sensors, a signal from the touch-sensitive pads 1490, a signal from the pressure sensors, a signal from the other device or system 1470, etc.

Although power source 1450, processor 1460, and communications interface 1480 are illustrated in FIG. 14 as being positioned in haptic device 1420, the present disclosure is not so limited. For example, one or more of power source 1450, processor 1460, or communications interface 1480 may be positioned within haptic device 1410 or within another wearable textile.

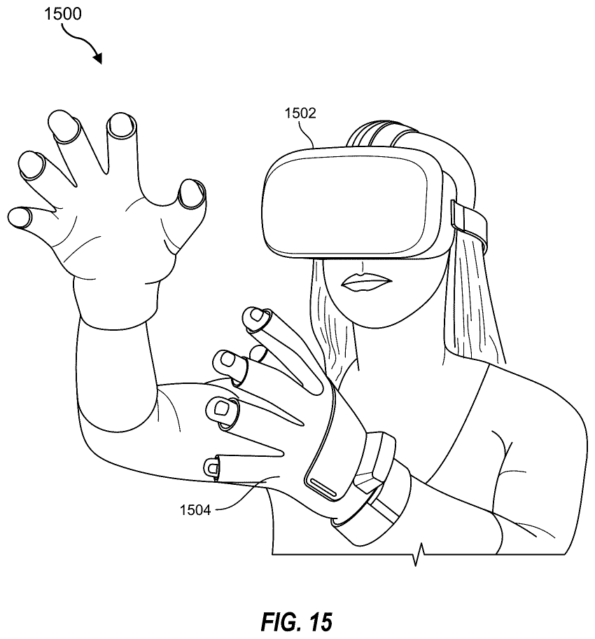

Haptic wearables, such as those shown in and described in connection with FIG. 14, may be implemented in a variety of types of artificial-reality systems and environments. FIG. 15 shows an example artificial-reality environment 1500 including one head-mounted virtual-reality display and two haptic devices (i.e., gloves), and in other embodiments any number and/or combination of these components and other components may be included in an artificial-reality system. For example, in some embodiments there may be multiple head-mounted displays each having an associated haptic device, with each head-mounted display and each haptic device communicating with the same console, portable computing device, or other computing system.

Head-mounted display 1502 generally represents any type or form of virtual-reality system, such as virtual-reality system 1300 in FIG. 13. Haptic device 1504 generally represents any type or form of wearable device, worn by a user of an artificial-reality system, that provides haptic feedback to the user to give the user the perception that he or she is physically engaging with a virtual object. In some embodiments, haptic device 1504 may provide haptic feedback by applying vibration, motion, and/or force to the user. For example, haptic device 1504 may limit or augment a user's movement. To give a specific example, haptic device 1504 may limit a user's hand from moving forward so that the user has the perception that his or her hand has come in physical contact with a virtual wall. In this specific example, one or more actuators within the haptic device may achieve the physical-movement restriction by pumping fluid into an inflatable bladder of the haptic device. In some examples, a user may also use haptic device 1504 to send action requests to a console. Examples of action requests include, without limitation, requests to start an application and/or end the application and/or requests to perform a particular action within the application.

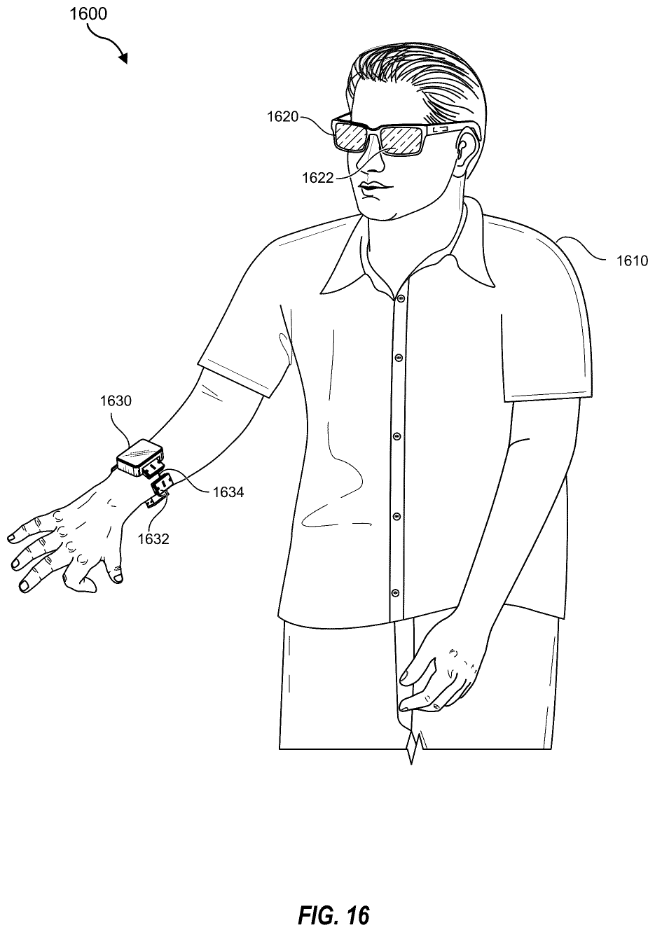

While haptic interfaces may be used with virtual-reality systems, as shown in FIG. 15, haptic interfaces may also be used with augmented-reality systems, as shown in FIG. 16. FIG. 16 is a perspective view of a user 1610 interacting with an augmented-reality system 1600. In this example, user 1610 may wear a pair of augmented-reality glasses 1620 that may have one or more displays 1622 and that are paired with a haptic device 1630. In this example, haptic device 1630 may be a wristband that includes a plurality of band elements 1632 and a tensioning mechanism 1634 that connects band elements 1632 to one another.

One or more of band elements 1632 may include any type or form of actuator suitable for providing haptic feedback. For example, one or more of band elements 1632 may be configured to provide one or more of various types of cutaneous feedback, including vibration, force, traction, texture, and/or temperature. To provide such feedback, band elements 1632 may include one or more of various types of actuators. In one example, each of band elements 1632 may include a vibrotactor (e.g., a vibrotactile actuator) configured to vibrate in unison or independently to provide one or more of various types of haptic sensations to a user. Alternatively, only a single band element or a subset of band elements may include vibrotactors.

Haptic devices 1410, 1420, 1504, and 1630 may include any suitable number and/or type of haptic transducer, sensor, and/or feedback mechanism. For example, haptic devices 1410, 1420, 1504, and 1630 may include one or more mechanical transducers, piezoelectric transducers, and/or fluidic transducers. Haptic devices 1410, 1420, 1504, and 1630 may also include various combinations of different types and forms of transducers that work together or independently to enhance a user's artificial-reality experience. In one example, each of band elements 1632 of haptic device 1630 may include a vibrotactor (e.g., a vibrotactile actuator) configured to vibrate in unison or independently to provide one or more of various types of haptic sensations to a user.

In some embodiments, the systems described herein may also include an eye-tracking subsystem designed to identify and track various characteristics of a user's eye(s), such as the user's gaze direction. The phrase “eye tracking” may, in some examples, refer to a process by which the position, orientation, and/or motion of an eye is measured, detected, sensed, determined, and/or monitored. The disclosed systems may measure the position, orientation, and/or motion of an eye in a variety of different ways, including through the use of various optical-based eye-tracking techniques, ultrasound-based eye-tracking techniques, etc. An eye-tracking subsystem may be configured in a number of different ways and may include a variety of different eye-tracking hardware components or other computer-vision components. For example, an eye-tracking subsystem may include a variety of different optical sensors, such as two-dimensional (2D) or 3D cameras, time-of-flight depth sensors, single-beam or sweeping laser rangefinders, 3D LiDAR sensors, and/or any other suitable type or form of optical sensor. In this example, a processing subsystem may process data from one or more of these sensors to measure, detect, determine, and/or otherwise monitor the position, orientation, and/or motion of the user's eye(s).

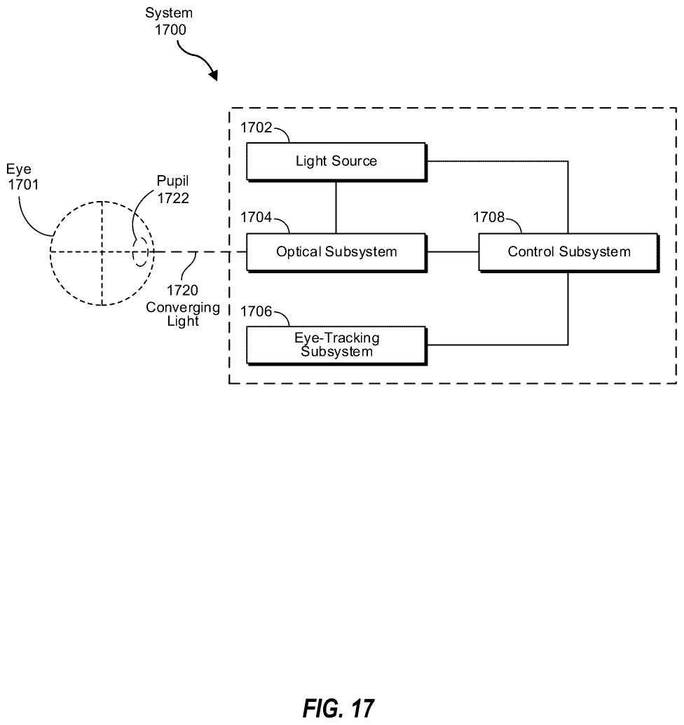

FIG. 17 is an illustration of an exemplary system 1700 that incorporates an eye-tracking subsystem capable of tracking a user's eye(s). As depicted in FIG. 17, system 1700 may include a light source 1702, an optical subsystem 1704, an eye-tracking subsystem 1706, and/or a control subsystem 1708. In some examples, light source 1702 may generate light for an image (e.g., to be presented to an eye 1701 of the viewer). Light source 1702 may represent any of a variety of suitable devices. For example, light source 1702 can include a two-dimensional projector (e.g., a LCoS display), a scanning source (e.g., a scanning laser), or other device (e.g., an LCD, an LED display, an OLED display, an active-matrix OLED display (AMOLED), a transparent OLED display (TOLED), a waveguide, or some other display capable of generating light for presenting an image to the viewer). In some examples, the image may represent a virtual image, which may refer to an optical image formed from the apparent divergence of light rays from a point in space, as opposed to an image formed from the light ray's actual divergence.

In some embodiments, optical subsystem 1704 may receive the light generated by light source 1702 and generate, based on the received light, converging light 1720 that includes the image. In some examples, optical subsystem 1704 may include any number of lenses (e.g., Fresnel lenses, convex lenses, concave lenses), apertures, filters, mirrors, prisms, and/or other optical components, possibly in combination with actuators and/or other devices. In particular, the actuators and/or other devices may translate and/or rotate one or more of the optical components to alter one or more aspects of converging light 1720. Further, various mechanical couplings may serve to maintain the relative spacing and/or the orientation of the optical components in any suitable combination.

In one embodiment, eye-tracking subsystem 1706 may generate tracking information indicating a gaze angle of an eye 1701 of the viewer. In this embodiment, control subsystem 1708 may control aspects of optical subsystem 1704 (e.g., the angle of incidence of converging light 1720) based at least in part on this tracking information. Additionally, in some examples, control subsystem 1708 may store and utilize historical tracking information (e.g., a history of the tracking information over a given duration, such as the previous second or fraction thereof) to anticipate the gaze angle of eye 1701 (e.g., an angle between the visual axis and the anatomical axis of eye 1701). In some embodiments, eye-tracking subsystem 1706 may detect radiation emanating from some portion of eye 1701 (e.g., the cornea, the iris, the pupil, or the like) to determine the current gaze angle of eye 1701. In other examples, eye-tracking subsystem 1706 may employ a wavefront sensor to track the current location of the pupil.

Any number of techniques can be used to track eye 1701. Some techniques may involve illuminating eye 1701 with infrared light and measuring reflections with at least one optical sensor that is tuned to be sensitive to the infrared light. Information about how the infrared light is reflected from eye 1701 may be analyzed to determine the position(s), orientation(s), and/or motion(s) of one or more eye feature(s), such as the cornea, pupil, iris, and/or retinal blood vessels.

In some examples, the radiation captured by a sensor of eye-tracking subsystem 1706 may be digitized (i.e., converted to an electronic signal). Further, the sensor may transmit a digital representation of this electronic signal to one or more processors (for example, processors associated with a device including eye-tracking subsystem 1706). Eye-tracking subsystem 1706 may include any of a variety of sensors in a variety of different configurations. For example, eye-tracking subsystem 1706 may include an infrared detector that reacts to infrared radiation. The infrared detector may be a thermal detector, a photonic detector, and/or any other suitable type of detector. Thermal detectors may include detectors that react to thermal effects of the incident infrared radiation.

In some examples, one or more processors may process the digital representation generated by the sensor(s) of eye-tracking subsystem 1706 to track the movement of eye 1701. In another example, these processors may track the movements of eye 1701 by executing algorithms represented by computer-executable instructions stored on non-transitory memory. In some examples, on-chip logic (e.g., an application-specific integrated circuit or ASIC) may be used to perform at least portions of such algorithms. As noted, eye-tracking subsystem 1706 may be programmed to use an output of the sensor(s) to track movement of eye 1701. In some embodiments, eye-tracking subsystem 1706 may analyze the digital representation generated by the sensors to extract eye rotation information from changes in reflections. In one embodiment, eye-tracking subsystem 1706 may use corneal reflections or glints (also known as Purkinje images) and/or the center of the eye's pupil 1722 as features to track over time.

In some embodiments, eye-tracking subsystem 1706 may use the center of the eye's pupil 1722 and infrared or near-infrared, non-collimated light to create corneal reflections. In these embodiments, eye-tracking subsystem 1706 may use the vector between the center of the eye's pupil 1722 and the corneal reflections to compute the gaze direction of eye 1701. In some embodiments, the disclosed systems may perform a calibration procedure for an individual (using, e.g., supervised or unsupervised techniques) before tracking the user's eyes. For example, the calibration procedure may include directing users to look at one or more points displayed on a display while the eye-tracking system records the values that correspond to each gaze position associated with each point.

In some embodiments, eye-tracking subsystem 1706 may use two types of infrared and/or near-infrared (also known as active light) eye-tracking techniques: bright-pupil and dark-pupil eye tracking, which may be differentiated based on the location of an illumination source with respect to the optical elements used. If the illumination is coaxial with the optical path, then eye 1701 may act as a retroreflector as the light reflects off the retina, thereby creating a bright pupil effect similar to a red-eye effect in photography. If the illumination source is offset from the optical path, then the eye's pupil 1722 may appear dark because the retroreflection from the retina is directed away from the sensor. In some embodiments, bright-pupil tracking may create greater iris/pupil contrast, allowing more robust eye tracking with iris pigmentation, and may feature reduced interference (e.g., interference caused by eyelashes and other obscuring features). Bright-pupil tracking may also allow tracking in lighting conditions ranging from total darkness to a very bright environment.

In some embodiments, control subsystem 1708 may control light source 1702 and/or optical subsystem 1704 to reduce optical aberrations (e.g., chromatic aberrations and/or monochromatic aberrations) of the image that may be caused by or influenced by eye 1701. In some examples, as mentioned above, control subsystem 1708 may use the tracking information from eye-tracking subsystem 1706 to perform such control. For example, in controlling light source 1702, control subsystem 1708 may alter the light generated by light source 1702 (e.g., by way of image rendering) to modify (e.g., pre-distort) the image so that the aberration of the image caused by eye 1701 is reduced.

The disclosed systems may track both the position and relative size of the pupil (since, e.g., the pupil dilates and/or contracts). In some examples, the eye-tracking devices and components (e.g., sensors and/or sources) used for detecting and/or tracking the pupil may be different (or calibrated differently) for different types of eyes. For example, the frequency range of the sensors may be different (or separately calibrated) for eyes of different colors and/or different pupil types, sizes, and/or the like. As such, the various eye-tracking components (e.g., infrared sources and/or sensors) described herein may need to be calibrated for each individual user and/or eye.

The disclosed systems may track both eyes with and without ophthalmic correction, such as that provided by contact lenses worn by the user. In some embodiments, ophthalmic correction elements (e.g., adjustable lenses) may be directly incorporated into the artificial reality systems described herein. In some examples, the color of the user's eye may necessitate modification of a corresponding eye-tracking algorithm. For example, eye-tracking algorithms may need to be modified based at least in part on the differing color contrast between a brown eye and, for example, a blue eye.

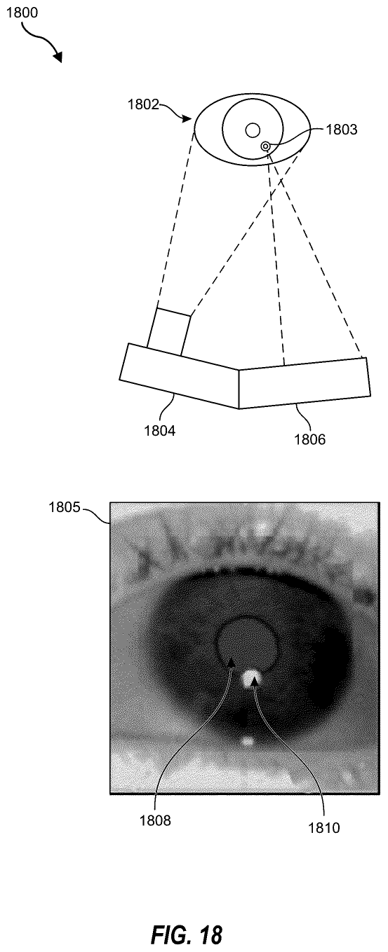

FIG. 18 is a more detailed illustration of various aspects of the eye-tracking subsystem illustrated in FIG. 17. As shown in this figure, an eye-tracking subsystem 1800 may include at least one source 1804 and at least one sensor 1806. Source 1804 generally represents any type or form of element capable of emitting radiation. In one example, source 1804 may generate visible, infrared, and/or near-infrared radiation. In some examples, source 1804 may radiate non-collimated infrared and/or near-infrared portions of the electromagnetic spectrum towards an eye 1802 of a user. Source 1804 may utilize a variety of sampling rates and speeds. For example, the disclosed systems may use sources with higher sampling rates in order to capture fixational eye movements of a user's eye 1802 and/or to correctly measure saccade dynamics of the user's eye 1802. As noted above, any type or form of eye-tracking technique may be used to track the user's eye 1802, including optical-based eye-tracking techniques, ultrasound-based eye-tracking techniques, etc.

Sensor 1806 generally represents any type or form of element capable of detecting radiation, such as radiation reflected off the user's eye 1802. Examples of sensor 1806 include, without limitation, a charge coupled device (CCD), a photodiode array, a complementary metal-oxide-semiconductor (CMOS) based sensor device, and/or the like. In one example, sensor 1806 may represent a sensor having predetermined parameters, including, but not limited to, a dynamic resolution range, linearity, and/or other characteristic selected and/or designed specifically for eye tracking.

As detailed above, eye-tracking subsystem 1800 may generate one or more glints. As detailed above, a glint 1803 may represent reflections of radiation (e.g., infrared radiation from an infrared source, such as source 1804) from the structure of the user's eye. In various embodiments, glint 1803 and/or the user's pupil may be tracked using an eye-tracking algorithm executed by a processor (either within or external to an artificial reality device). For example, an artificial reality device may include a processor and/or a memory device in order to perform eye tracking locally and/or a transceiver to send and receive the data necessary to perform eye tracking on an external device (e.g., a mobile phone, cloud server, or other computing device).

FIG. 18 shows an example image 1805 captured by an eye-tracking subsystem, such as eye-tracking subsystem 1800. In this example, image 1805 may include both the user's pupil 1808 and a glint 1810 near the same. In some examples, pupil 1808 and/or glint 1810 may be identified using an artificial-intelligence-based algorithm, such as a computer-vision-based algorithm. In one embodiment, image 1805 may represent a single frame in a series of frames that may be analyzed continuously in order to track the eye 1802 of the user. Further, pupil 1808 and/or glint 1810 may be tracked over a period of time to determine a user's gaze.

In one example, eye-tracking subsystem 1800 may be configured to identify and measure the inter-pupillary distance (IPD) of a user. In some embodiments, eye-tracking subsystem 1800 may measure and/or calculate the IPD of the user while the user is wearing the artificial reality system. In these embodiments, eye-tracking subsystem 1800 may detect the positions of a user's eyes and may use this information to calculate the user's IPD.

As noted, the eye-tracking systems or subsystems disclosed herein may track a user's eye position and/or eye movement in a variety of ways. In one example, one or more light sources and/or optical sensors may capture an image of the user's eyes. The eye-tracking subsystem may then use the captured information to determine the user's inter-pupillary distance, interocular distance, and/or a 3D position of each eye (e.g., for distortion adjustment purposes), including a magnitude of torsion and rotation (i.e., roll, pitch, and yaw) and/or gaze directions for each eye. In one example, infrared light may be emitted by the eye-tracking subsystem and reflected from each eye. The reflected light may be received or detected by an optical sensor and analyzed to extract eye rotation data from changes in the infrared light reflected by each eye.

The eye-tracking subsystem may use any of a variety of different methods to track the eyes of a user. For example, a light source (e.g., infrared light-emitting diodes) may emit a dot pattern onto each eye of the user. The eye-tracking subsystem may then detect (e.g., via an optical sensor coupled to the artificial reality system) and analyze a reflection of the dot pattern from each eye of the user to identify a location of each pupil of the user. Accordingly, the eye-tracking subsystem may track up to six degrees of freedom of each eye (i.e., 3D position, roll, pitch, and yaw) and at least a subset of the tracked quantities may be combined from two eyes of a user to estimate a gaze point (i.e., a 3D location or position in a virtual scene where the user is looking) and/or an IPD.

In some cases, the distance between a user's pupil and a display may change as the user's eye moves to look in different directions. The varying distance between a pupil and a display as viewing direction changes may be referred to as “pupil swim” and may contribute to distortion perceived by the user as a result of light focusing in different locations as the distance between the pupil and the display changes. Accordingly, measuring distortion at different eye positions and pupil distances relative to displays and generating distortion corrections for different positions and distances may allow mitigation of distortion caused by pupil swim by tracking the 3D position of a user's eyes and applying a distortion correction corresponding to the 3D position of each of the user's eyes at a given point in time. Thus, knowing the 3D position of each of a user's eyes may allow for the mitigation of distortion caused by changes in the distance between the pupil of the eye and the display by applying a distortion correction for each 3D eye position. Furthermore, as noted above, knowing the position of each of the user's eyes may also enable the eye-tracking subsystem to make automated adjustments for a user's IPD.

In some embodiments, a display subsystem may include a variety of additional subsystems that may work in conjunction with the eye-tracking subsystems described herein. For example, a display subsystem may include a varifocal subsystem, a scene-rendering module, and/or a vergence-processing module. The varifocal subsystem may cause left and right display elements to vary the focal distance of the display device. In one embodiment, the varifocal subsystem may physically change the distance between a display and the optics through which it is viewed by moving the display, the optics, or both. Additionally, moving or translating two lenses relative to each other may also be used to change the focal distance of the display. Thus, the varifocal subsystem may include actuators or motors that move displays and/or optics to change the distance between them. This varifocal subsystem may be separate from or integrated into the display subsystem. The varifocal subsystem may also be integrated into or separate from its actuation subsystem and/or the eye-tracking subsystems described herein.

In one example, the display subsystem may include a vergence-processing module configured to determine a vergence depth of a user's gaze based on a gaze point and/or an estimated intersection of the gaze lines determined by the eye-tracking subsystem. Vergence may refer to the simultaneous movement or rotation of both eyes in opposite directions to maintain single binocular vision, which may be naturally and automatically performed by the human eye. Thus, a location where a user's eyes are verged is where the user is looking and is also typically the location where the user's eyes are focused. For example, the vergence-processing module may triangulate gaze lines to estimate a distance or depth from the user associated with intersection of the gaze lines. The depth associated with intersection of the gaze lines may then be used as an approximation for the accommodation distance, which may identify a distance from the user where the user's eyes are directed. Thus, the vergence distance may allow for the determination of a location where the user's eyes should be focused and a depth from the user's eyes at which the eyes are focused, thereby providing information (such as an object or plane of focus) for rendering adjustments to the virtual scene.

The vergence-processing module may coordinate with the eye-tracking subsystems described herein to make adjustments to the display subsystem to account for a user's vergence depth. When the user is focused on something at a distance, the user's pupils may be slightly farther apart than when the user is focused on something close. The eye-tracking subsystem may obtain information about the user's vergence or focus depth and may adjust the display subsystem to be closer together when the user's eyes focus or verge on something close and to be farther apart when the user's eyes focus or verge on something at a distance.

The eye-tracking information generated by the above-described eye-tracking subsystems may also be used, for example, to modify various aspect of how different computer-generated images are presented. For example, a display subsystem may be configured to modify, based on information generated by an eye-tracking subsystem, at least one aspect of how the computer-generated images are presented. For instance, the computer-generated images may be modified based on the user's eye movement, such that if a user is looking up, the computer-generated images may be moved upward on the screen. Similarly, if the user is looking to the side or down, the computer-generated images may be moved to the side or downward on the screen. If the user's eyes are closed, the computer-generated images may be paused or removed from the display and resumed once the user's eyes are back open.

The above-described eye-tracking subsystems can be incorporated into one or more of the various artificial reality systems described herein in a variety of ways. For example, one or more of the various components of system 1700 and/or eye-tracking subsystem 1800 may be incorporated into augmented-reality system 1200 in FIG. 12 and/or virtual-reality system 1300 in FIG. 13 to enable these systems to perform various eye-tracking tasks (including one or more of the eye-tracking operations described herein).

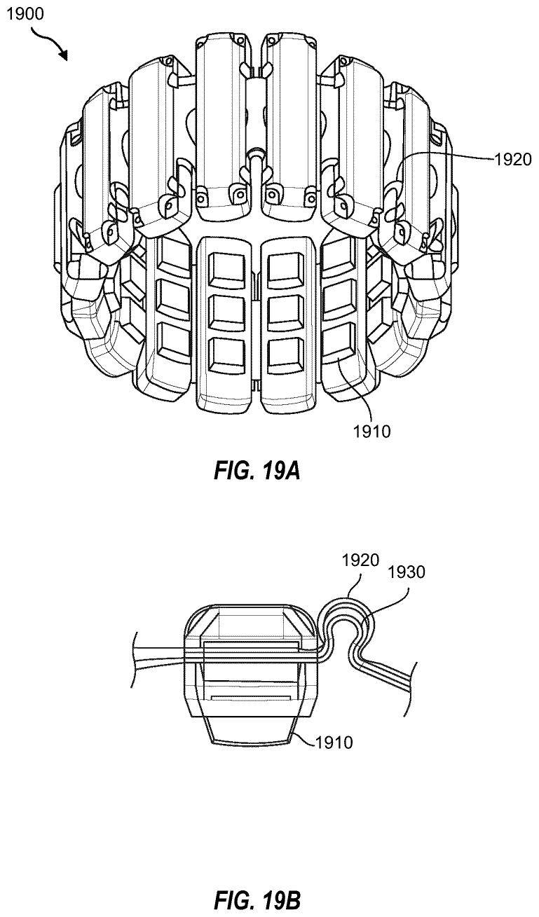

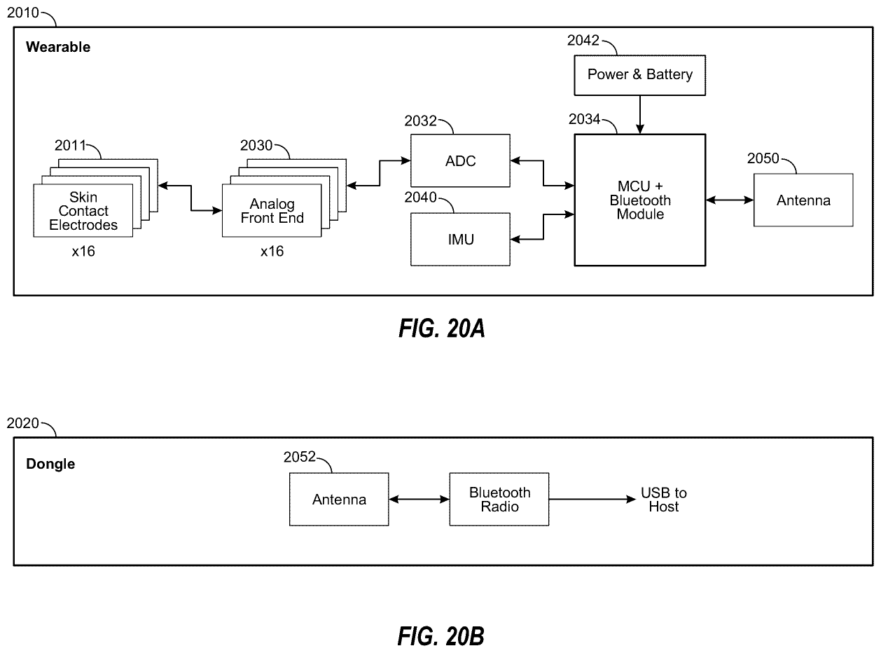

FIG. 19A illustrates an exemplary human-machine interface (also referred to herein as an EMG control interface) configured to be worn around a user's lower arm or wrist as a wearable system 1900. In this example, wearable system 1900 may include sixteen neuromuscular sensors 1910 (e.g., EMG sensors) arranged circumferentially around an elastic band 1920 with an interior surface 1930 configured to contact a user's skin. However, any suitable number of neuromuscular sensors may be used. The number and arrangement of neuromuscular sensors may depend on the particular application for which the wearable device is used. For example, a wearable armband or wristband can be used to generate control information for controlling an augmented reality system, a robot, controlling a vehicle, scrolling through text, controlling a virtual avatar, or any other suitable control task. As shown, the sensors may be coupled together using flexible electronics incorporated into the wireless device. FIG. 19B illustrates a cross-sectional view through one of the sensors of the wearable device shown in FIG. 19A. In some embodiments, the output of one or more of the sensing components can be optionally processed using hardware signal processing circuitry (e.g., to perform amplification, filtering, and/or rectification). In other embodiments, at least some signal processing of the output of the sensing components can be performed in software. Thus, signal processing of signals sampled by the sensors can be performed in hardware, software, or by any suitable combination of hardware and software, as aspects of the technology described herein are not limited in this respect. A non-limiting example of a signal processing chain used to process recorded data from sensors 1910 is discussed in more detail below with reference to FIGS. 20A and 20B.

FIGS. 20A and 20B illustrate an exemplary schematic diagram with internal components of a wearable system with EMG sensors. As shown, the wearable system may include a wearable portion 2010 (FIG. 20A) and a dongle portion 2020 (FIG. 20B) in communication with the wearable portion 2010 (e.g., via BLUETOOTH or another suitable wireless communication technology). As shown in FIG. 20A, the wearable portion 2010 may include skin contact electrodes 2011, examples of which are described in connection with FIGS. 19A and 19B. The output of the skin contact electrodes 2011 may be provided to analog front end 2030, which may be configured to perform analog processing (e.g., amplification, noise reduction, filtering, etc.) on the recorded signals. The processed analog signals may then be provided to analog-to-digital converter 2032, which may convert the analog signals to digital signals that can be processed by one or more computer processors. An example of a computer processor that may be used in accordance with some embodiments is microcontroller (MCU) 2034, illustrated in FIG. 20A. As shown, MCU 2034 may also include inputs from other sensors (e.g., IMU sensor 2040), and power and battery module 2042. The output of the processing performed by MCU 2034 may be provided to antenna 2050 for transmission to dongle portion 2020 shown in FIG. 20B.

Dongle portion 2020 may include antenna 2052, which may be configured to communicate with antenna 2050 included as part of wearable portion 2010. Communication between antennas 2050 and 2052 may occur using any suitable wireless technology and protocol, non-limiting examples of which include radiofrequency signaling and BLUETOOTH. As shown, the signals received by antenna 2052 of dongle portion 2020 may be provided to a host computer for further processing, display, and/or for effecting control of a particular physical or virtual object or objects.

Although the examples provided with reference to FIGS. 19A-19B and FIGS. 20A-20B are discussed in the context of interfaces with EMG sensors, the techniques described herein for reducing electromagnetic interference can also be implemented in wearable interfaces with other types of sensors including, but not limited to, mechanomyography (MMG) sensors, sonomyography (SMG) sensors, and electrical impedance tomography (EIT) sensors. The techniques described herein for reducing electromagnetic interference can also be implemented in wearable interfaces that communicate with computer hosts through wires and cables (e.g., USB cables, optical fiber cables, etc.).

The following example embodiments are also included in the present disclosure:

Example 1. A circuit assembly including: a first sub-package including a first chiplet including an active frontside that includes active circuitry and faces in a first direction; a second sub-package including a second chiplet including an active frontside that includes active circuitry and faces in a second direction opposite the first direction; and a memory sub-package including a memory, wherein the first sub-package, the second sub-package, and the memory sub-package are arranged so as to overlap each other in the first direction.

Example 2. The circuit assembly of Example 1, wherein at least one of the first sub-package or the second sub-package includes at least one redistribution layer (RDL).

Example 3. The circuit assembly of Example 2, wherein the first chiplet is electrically coupled to the second chiplet by the at least one RDL.

Example 4. The circuit assembly of Example 2 or Example 3, wherein the memory sub-package is electrically coupled to the first chiplet and the second chiplet by the at least one RDL.

Example 5. The circuit assembly of any one of Examples 1 through 4, wherein each of the first sub-package and the second sub-package includes at least one RDL.

Example 6. The circuit assembly of Example 5, wherein the first chiplet is electrically coupled to the second chiplet by the at least one RDL of the first chiplet and the at least one RDL of the second chiplet.

Example 7. The circuit assembly of any one of Examples 1 through 6, wherein the active frontside of the first sub-package faces toward the active frontside of the second sub-package.

Example 8. The circuit assembly of any one of Examples 1 through 6, wherein the active frontside of the first sub-package faces away from the active frontside of the second sub-package.

Example 9. The circuit assembly of any one of Examples 1 through 8, wherein: the first sub-package includes a frontside RDL adjacent the active frontside of the first chiplet; and the frontside RDL is electrically coupled to the active frontside of the first chiplet.

Example 10. The circuit assembly of Example 9, wherein the first sub-package further includes a backside RDL adjacent a backside of the first chiplet that is opposite the active frontside of the first chiplet, wherein the backside RDL of the first sub-package is electrically coupled to the frontside RDL of the first sub-package by a plurality of vias.

Example 11. The circuit assembly of Example 9 or Example 10, wherein the active frontside of the first chiplet is electrically coupled to the active frontside of the second chiplet by a plurality of vias passing through the frontside RDL of the first sub-package.

Example 12. The circuit assembly of any one of Examples 1 through 11, further including a plurality of integrated passive devices (IPDs) electrically mounted on at least one of the first sub-package or the second sub-package.

Example 13. The circuit assembly of Example 12, wherein at least one of the plurality of IPDs is disposed between the memory sub-package and at least one of the first sub-package or the second sub-package.

Example 14. The circuit assembly of Example 12 or Example 13, wherein at least one of the plurality of IPDs is disposed on a surface of at least one of the first sub-package or the second sub-package facing away from the memory sub-package.

Example 15. The circuit assembly of any one of Examples 1 through 14, further including a plurality of interconnects electrically coupling the memory sub-package to at least one of the first sub-package or the second sub-package.

Example 16. The circuit assembly of Example 15, wherein:
the plurality of interconnects spans, in the first direction, a gap between the memory sub-package the first sub-package or the second sub-package; and
at least one IPD is positioned within the gap.

Example 17. A circuit assembly including: a first sub-package including a first chiplet including an active frontside that includes active circuitry and faces in a first direction; a second chiplet including an active frontside that includes active circuitry and faces in a second direction opposite the first direction; and a memory sub-package including a memory, wherein the second chiplet is positioned between the first sub-package and the memory sub-package.

Example 18. The circuit assembly of Example 17, wherein: the first sub-package includes a frontside RDL adjacent the active frontside of the first chiplet; and the active frontside of the second chiplet is electrically coupled to the active frontside of the first chiplet by a plurality of vias passing through the frontside RDL of the first sub-package.

Example 19. A method including: electrically coupling a first sub-package including a first chiplet to a second sub-package including a second chiplet such that an active frontside of the first chiplet faces in a first direction and an active frontside of the second chiplet faces in a second direction opposite the first direction, wherein the active frontside of the first chiplet and the active frontside of the second chiplet each includes active circuitry; and electrically coupling a memory sub-package including a memory to at least one of the first sub-package or the second sub-package.

Example 20. The method of Example 19, further including mounting at least one IPD to at least one of the first sub-package or the second sub-package such that the at least one IPD is positioned between the memory sub-package and the at least one of the first sub-package or the second sub-package.

The process parameters and sequence of the steps described and/or illustrated herein are given by way of example only and can be varied as desired. For example, while the steps illustrated and/or described herein may be shown or discussed in a particular order, these steps do not necessarily need to be performed in the order illustrated or discussed. The various example methods described and/or illustrated herein may also omit one or more of the steps described or illustrated herein or include additional steps in addition to those disclosed.

The preceding description has been provided to enable others skilled in the art to best utilize various aspects of the example embodiments disclosed herein. This example description is not intended to be exhaustive or to be limited to any precise form disclosed. Many modifications and variations are possible without departing from the spirit and scope of the present disclosure. The embodiments disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and/or claims, are to be construed as permitting both direct and indirect (i.e., via other elements or components) connection. In addition, the terms “a” or “an,” as used in the specification and/or claims, are to be construed as meaning “at least one of.” Finally, for ease of use, the terms “including” and “having” (and their derivatives), as used in the specification and/or claims, are interchangeable with and have the same meaning as the word “comprising.”

What is claimed is:

1. A circuit assembly comprising:
a first sub-package comprising a first chiplet including an active frontside that comprises active circuitry and faces in a first direction;
a second sub-package comprising a second chiplet including an active frontside that comprises active circuitry and faces in a second direction opposite the first direction; and
a memory sub-package comprising a memory, wherein the first sub-package, the second sub-package, and the memory sub-package are arranged so as to overlap each other in the first direction.

2. The circuit assembly of claim 1, wherein at least one of the first sub-package or the second sub-package comprises at least one redistribution layer (RDL).

3. The circuit assembly of claim 2, wherein the first chiplet is electrically coupled to the second chiplet by the at least one RDL.

4. The circuit assembly of claim 2, wherein the memory sub-package is electrically coupled to the first chiplet and the second chiplet by the at least one RDL.

5. The circuit assembly of claim 1, wherein each of the first sub-package and the second sub-package comprises at least one RDL.

6. The circuit assembly of claim 5, wherein the first chiplet is electrically coupled to the second chiplet by the at least one RDL of the first chiplet and the at least one RDL of the second chiplet.

7. The circuit assembly of claim 1, wherein the active frontside of the first sub-package faces toward the active frontside of the second sub-package.

8. The circuit assembly of claim 1, wherein the active frontside of the first sub-package faces away from the active frontside of the second sub-package.

9. The circuit assembly of claim 1, wherein:
the first sub-package comprises a frontside RDL adjacent the active frontside of the first chiplet; and
the frontside RDL is electrically coupled to the active frontside of the first chiplet.

10. The circuit assembly of claim 9, wherein the first sub-package further comprises a backside RDL adjacent a backside of the first chiplet that is opposite the active frontside of the first chiplet, wherein the backside RDL of the first sub-package is electrically coupled to the frontside RDL of the first sub-package by a plurality of vias.

11. The circuit assembly of claim 9, wherein the active frontside of the first chiplet is electrically coupled to the active frontside of the second chiplet by a plurality of vias passing through the frontside RDL of the first sub-package.

12. The circuit assembly of claim 1, further comprising a plurality of integrated passive devices (IPDs) electrically mounted on at least one of the first sub-package or the second sub-package.

13. The circuit assembly of claim 12, wherein at least one of the plurality of IPDs is disposed between the memory sub-package and at least one of the first sub-package or the second sub-package.

14. The circuit assembly of claim 12, wherein at least one of the plurality of IPDs is disposed on a surface of at least one of the first sub-package or the second sub-package facing away from the memory sub-package.

15. The circuit assembly of claim 1, further comprising a plurality of interconnects electrically coupling the memory sub-package to at least one of the first sub-package or the second sub-package.

16. The circuit assembly of claim 15, wherein:
the plurality of interconnects spans, in the first direction, a gap between the memory sub-package the first sub-package or the second sub-package; and
at least one IPD is positioned within the gap.

17. A circuit assembly comprising:
a first sub-package comprising a first chiplet including an active frontside that comprises active circuitry and faces in a first direction;
a second chiplet including an active frontside that comprises active circuitry and faces in a second direction opposite the first direction; and
a memory sub-package comprising a memory, wherein the second chiplet is positioned between the first sub-package and the memory sub-package.

18. The circuit assembly of claim 17, wherein:
the first sub-package comprises a frontside RDL adjacent the active frontside of the first chiplet; and
the active frontside of the second chiplet is electrically coupled to the active frontside of the first chiplet by a plurality of vias passing through the frontside RDL of the first sub-package.

19. A method comprising:
electrically coupling a first sub-package comprising a first chiplet to a second sub-package comprising a second chiplet such that an active frontside of the first chiplet faces in a first direction and an active frontside of the second chiplet faces in a second direction opposite the first direction, wherein the active frontside of the first chiplet and the active frontside of the second chiplet each comprises active circuitry; and
electrically coupling a memory sub-package comprising a memory to at least one of the first sub-package or the second sub-package.

20. The method of claim 19, further comprising mounting at least one IPD to at least one of the first sub-package or the second sub-package such that the at least one IPD is positioned between the memory sub-package and the at least one of the first sub-package or the second sub-package.
